(19) United States
(12) Patent Application Publication
(10) Pub. No.: US 2024/0215459 A1
(43) Pub. Date: Jun. 27, 2024

(54) MEMORY DEVICE

(71) Applicant: Kioxia Corporation, Tokyo (JP)

(72) Inventors: Takeshi IWASAKI, Kuwana (JP); Yosuke MATSUSHIMA, Yokkaichi (JP); Makoto ONIZAKI, Tokyo (JP); Katsuyoshi KOMATSU, Yokkaichi (JP); Masakazu GOTO, Moriya (JP); Hiroki KAWAI, Inazawa (JP); Rina NOMOTO, Tokyo (JP); Kenta CHOKAWA, Yokkaichi (JP); Zhu QI, Yokkaichi (JP); Tadaomi DAIBOU, Yokkaichi (JP)

(73) Assignee: Kioxia Corporation, Tokyo (JP)

(21) Appl. No.: 18/476,628

(22) Filed: Sep. 28, 2023

(30) Foreign Application Priority Data
Dec. 21, 2022 (JP) 2022-204150
Jul. 14, 2023 (JP) 2023-116214

(51) Int. Cl. H10N 50/85; H10B 61/00; H10N 50/20

(52) U.S. Cl. CPC H10N 50/85; H10B 61/00; H10N 50/20

(57) ABSTRACT

A memory device of embodiments includes a memory cell including: a first conductive layer; a second conductive layer; a third conductive layer provided between the first conductive layer and the second conductive layer; a variable resistance layer provided between the first conductive layer and the third conductive layer; and a switching layer provided between the third conductive layer and the second conductive layer. The switching layer contains an oxide of a first element, which is at least one element selected from a group consisting of zirconium, yttrium, tantalum, lanthanum, cerium, titanium, hafnium, and magnesium, and a compound of a second element that is at least one element selected from a group consisting of zinc, tin, gallium, indium, and bismuth and a third element that is at least one element selected from a group consisting of tellurium, sulfur, and selenium.

### CROSS-REFERENCE TO RELATED APPLICATION

This application is based upon and claims the benefit of priority from Japanese Patent Application No. 2022-204150, filed on Dec. 21, 2022, and Japanese Patent Application No. 2023-116214, filed on Jul. 14, 2023, the entire contents of which are incorporated herein by reference.

### FIELD

Embodiments described herein relate generally to a memory device.

### BACKGROUND

As a large-capacity nonvolatile memory device, there is a cross-point type two-terminal memory device. With the cross-point type two-terminal memory device, scaling-down and high integration of memory cells can be realized.

Each memory cell of the cross-point type two-terminal memory device has, for example, a variable resistance element and a switching element. Since the memory cell has a switching element, the current flowing through memory cells other than the selected memory cell is suppressed.

The switching element is required to have excellent characteristics, such as low leakage current, high on-current, and high reliability.

### BRIEF DESCRIPTION OF THE DRAWINGS

FIG. 1 is a block diagram of a memory device according to a first embodiment;

FIG. 2 is a schematic cross-sectional view of a memory cell in the memory device according to the first embodiment;

FIGS. 3A and 3B are diagrams showing analysis results of the memory device according to the first embodiment;

FIGS. 4A and 4B are diagrams showing analysis results of the memory device according to the first embodiment;

FIG. 5 is a diagram showing an example of a chemical composition of a switching layer in the memory device according to the first embodiment;

FIG. 6 is an explanatory diagram of a problem of the memory device according to the first embodiment;

FIG. 7 is an explanatory diagram of the current-voltage characteristics of a switching element according to the first embodiment;

FIG. 8 is an explanatory diagram of the function and effect of the memory device according to the first embodiment;

FIG. 9 is a schematic cross-sectional view of a memory cell in a memory device according to a first modification example of the first embodiment;

FIG. 10 is a schematic cross-sectional view of a memory cell in a memory device according to a second modification example of the first embodiment;

FIG. 11 is a schematic cross-sectional view of a memory cell in a memory device according to a third modification example of the first embodiment;

FIG. 12 is a schematic cross-sectional view of a memory cell in a memory device according to a second embodiment;

FIG. 13 is a schematic cross-sectional view of a memory cell in a memory device according to a third embodiment;

FIG. 14 is an explanatory diagram of the current-voltage characteristics of a memory element according to the third embodiment;

FIG. 15 is an explanatory diagram of a first operation example of the memory operation in the memory device according to the third embodiment;

FIG. 16 is an explanatory diagram of a second operation example of the memory operation in the memory device according to the third embodiment;

FIG. 17 is an explanatory diagram of the current-voltage characteristics of a memory element according to a first modification example of the third embodiment;

FIG. 18 is an explanatory diagram of a third operation example of the memory operation in the memory device according to the first modification example of the third embodiment;

FIG. 19 is an explanatory diagram of a fourth operation example of the memory operation in the memory device according to the first modification example of the third embodiment;

FIG. 20 is an explanatory diagram of the current-voltage characteristics of a memory element according to a second modification example of the third embodiment;

FIG. 21 is an explanatory diagram of a fifth operation example of the memory operation in the memory device according to the second modification example of the third embodiment;

FIG. 22 is an explanatory diagram of a sixth operation example of the memory operation in the memory device according to the second modification example of the third embodiment;

FIG. 23 is an explanatory diagram of the current-voltage characteristics of a memory element according to a third modification example of the third embodiment;

FIG. 24 is an explanatory diagram of a seventh operation example of the memory operation in the memory device according to the third modification example of the third embodiment;

FIG. 25 is an explanatory diagram of an eighth operation example of the memory operation in the memory device according to the third modification example of the third embodiment;

FIG. 26 is a schematic cross-sectional view of a memory cell in a memory device according to a fourth embodiment;

FIG. 27 is a schematic cross-sectional view of a memory cell in a memory device according to a first modification example of the fourth embodiment;

FIG. 28 is a schematic cross-sectional view of a memory cell in a memory device according to a second modification example of the fourth embodiment;

FIG. 29 is a schematic cross-sectional view of a memory cell in a memory device according to a third modification example of the fourth embodiment;

FIG. 30 is a schematic cross-sectional view of a memory cell in a memory device according to a fifth embodiment;

FIG. 31 is a schematic cross-sectional view of a memory cell in a memory device according to a sixth embodiment;

FIG. 32 is a schematic cross-sectional view of a memory cell in a memory device according to a seventh embodiment;

FIG. 33 is a schematic cross-sectional view of a memory cell in a memory device according to an eighth embodiment; and

FIG. 34 is a schematic cross-sectional view of a memory cell in a memory device according to a ninth embodiment.

### DETAILED DESCRIPTION

A memory device of embodiments includes a memory cell including: a first conductive layer; a second conductive layer; a third conductive layer provided between the first conductive layer and the second conductive layer; a variable resistance layer provided between the first conductive layer and the third conductive layer; and a switching layer provided between the third conductive layer and the second conductive layer. The switching layer contains an oxide of a first element and a compound of a second element and a third element. The first element is at least one element selected from a group consisting of zirconium (Zr), yttrium (Y), tantalum (Ta), lanthanum (La), cerium (Ce), titanium (Ti), hafnium (Hf), and magnesium (Mg). The second element is at least one element selected from a group consisting of zinc (Zn), tin (Sn), gallium (Ga), indium (In), and bismuth (Bi). The third element is at least one element selected from a group consisting of tellurium (Te), sulfur (S), and selenium (Se).

Hereinafter, embodiments will be described with reference to the diagrams. In addition, in the following description, the same or similar members and the like are denoted by the same reference numerals, and the description of the members and the like once described will be omitted as appropriate.

The qualitative analysis and quantitative analysis of the chemical composition forming the memory device in this specification can be performed by using, for example, Rutherford Backscattering Spectroscopy (RBS), secondary ion mass spectroscopy (SIMS), energy dispersive X-ray spectroscopy (EDX), or electron energy loss spectroscopy (EELS). In addition, when measuring the thickness of each member forming the memory device, a distance between members, and the like, for example, a transmission electron microscope (TEM) can be used. In addition, for the identification of the constituent materials of members forming the memory device and the measurement of an abundance ratio, a bonding state, a local structure (interatomic distance, coordination number), and a chemical state, for example, X-ray photoelectron spectroscopy (XPS), X-ray absorption fine structure (XAFS), Raman spectroscopy (Raman), or EELS can be used.

### First Embodiment

A memory device according to a first embodiment includes a memory cell including: a first conductive layer; a second conductive layer; a third conductive layer provided between the first conductive layer and the second conductive layer; a variable resistance layer provided between the first conductive layer and the third conductive layer; and a switching layer provided between the third conductive layer and the second conductive layer. In addition, the switching layer contains an oxide of a first element and a compound of a second element and a third element. The first element is at least one element selected from a group consisting of zirconium (Zr), yttrium (Y), tantalum (Ta), lanthanum (La), cerium (Ce), titanium (Ti), hafnium (Hf), and magnesium (Mg). The second element is at least one element selected from a group consisting of zinc (Zn), tin (Sn), gallium (Ga), indium (In), and bismuth (Bi). The third element is at least one element selected from a group consisting of tellurium (Te), sulfur (S), and selenium (Se).

In addition, the memory device according to the first embodiment further includes: a plurality of first wirings; and a plurality of second wirings crossing the plurality of first wirings. In addition, the memory cell is provided in a region where one of the plurality of first wirings and one of the plurality of second wirings cross each other.

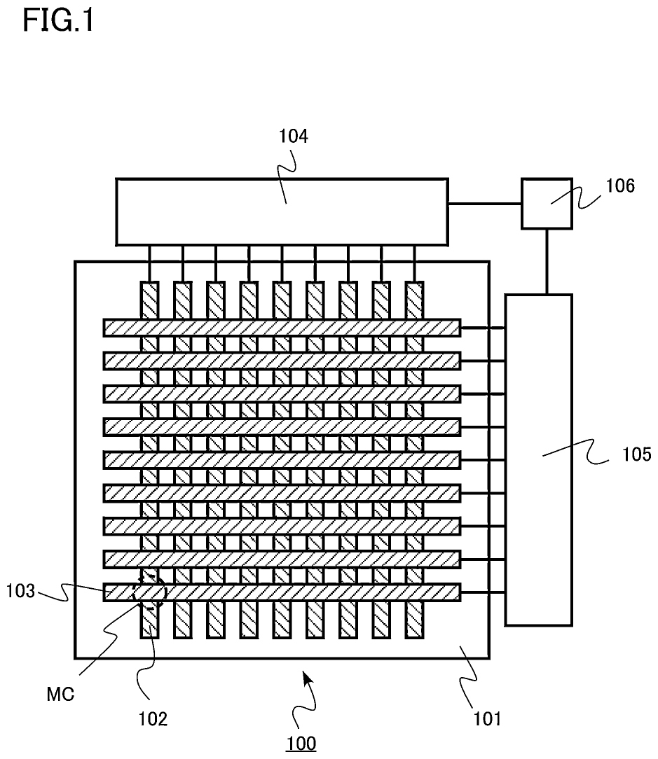

FIG. 1 is a block diagram of the memory device according to the first embodiment.

A memory cell array 100 in the memory device according to the first embodiment includes, for example, a plurality of word lines 102 and a plurality of bit lines 103 crossing the word lines 102 on a semiconductor substrate 101 with an insulating layer interposed therebetween. The bit lines 103 are provided in a layer above the word lines 102, for example. In addition, a first control circuit 104, a second control circuit 105, and a sense circuit 106 are provided as peripheral circuits around the memory cell array 100.

The word line 102 is an example of the first wiring. In addition, the bit line 103 is an example of the second wiring.

A plurality of memory cells MC are provided in regions where the word lines 102 and the bit lines 103 cross each other. The memory device according to the first embodiment is a two-terminal magnetoresistive memory having a cross-point structure.

Each of the plurality of word lines 102 is connected to the first control circuit 104. In addition, each of the plurality of bit lines 103 is connected to the second control circuit 105. The sense circuit 106 is connected to the first control circuit 104 and the second control circuit 105.

The first control circuit 104 and the second control circuit 105 have functions of selecting a desired memory cell MC, writing data to the memory cell MC, reading data from the memory cell MC, and deleting data from the memory cell MC, for example. When reading data, the data in the memory cell MC is read as the amount of current flowing between the word line 102 and the bit line 103 or as a potential change of the bit line 103. The sense circuit 106 has a function of determining the amount of current to determine the polarity of the data. For example, “0” and “1” of data are determined.

The first control circuit 104, the second control circuit 105, and the sense circuit 106 are electronic circuits using semiconductor devices formed on the semiconductor substrate 101, for example.

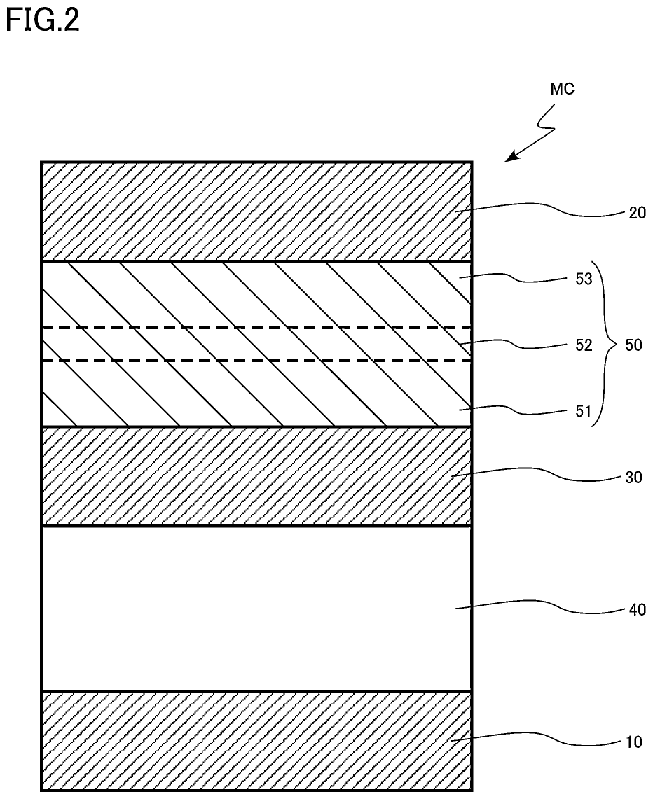

FIG. 2 is a schematic cross-sectional view of a memory cell in the memory device according to the first embodiment. FIG. 2 shows a cross section of one memory cell MC indicated by, for example, a dotted circle in the memory cell array 100 of FIG. 1.

As shown in FIG. 2, the memory cell MC includes a lower electrode 10, an upper electrode 20, an intermediate electrode 30, a switching layer 40, and a variable resistance layer 50. The variable resistance layer 50 includes a fixed layer 51, a tunnel layer 52, and a free layer 53.

The lower electrode 10 is an example of the first conductive layer. The upper electrode 20 is an example of the second conductive layer. The intermediate electrode 30 is an example of the third conductive layer.

The lower electrode 10, the switching layer 40, and the intermediate electrode 30 form a switching element of the memory cell MC. The intermediate electrode 30, the variable resistance layer 50, and the upper electrode 20 form a variable resistance element of the memory cell MC.

The lower electrode 10 is connected to the word line 102. The lower electrode 10 is, for example, a metal. The lower electrode 10 contains, for example, at least one material selected from a group consisting of carbon, carbon nitride, tungsten, tungsten carbide, and tungsten nitride. The lower electrode 10 may be a part of the word line 102.

The upper electrode 20 is connected to the bit line 103. The upper electrode 20 is, for example, a metal. The upper electrode 20 contains, for example, at least one material selected from a group consisting of carbon, carbon nitride, tungsten, tungsten carbide, and tungsten nitride. The upper electrode 20 may be a part of the bit line 103.

The intermediate electrode 30 is provided between the lower electrode 10 and the upper electrode 20. The intermediate electrode 30 is, for example, a metal. The intermediate electrode 30 contains, for example, at least one material selected from a group consisting of carbon, carbon nitride, tungsten, tungsten carbide, and tungsten nitride.

The switching layer 40 is provided between the lower electrode 10 and the intermediate electrode 30. The thickness of the switching layer 40 in a first direction from the lower electrode 10 to the upper electrode 20 is, for example, equal to or more than 5 nm and equal to or less than 50 nm. It is preferable that the thickness of the switching layer 40 in the first direction from the lower electrode 10 to the upper electrode 20 is, for example, equal to or more than 5 nm and equal to or less than 20 nm.

The switching layer 40 has a function of suppressing an increase in half-select leakage current flowing through the half-selected cell. The switching layer 40 has a nonlinear current-voltage characteristic that a current increases abruptly at a specific threshold voltage.

The switching layer 40 includes an oxide and a chalcogenide. The chalcogenide is a compound in which tellurium (Te), sulfur (S), or selenium (Se), which is a chalcogen element, is combined with other elements.

The switching layer 40 contains an oxide of a first element that is at least one element selected from a group consisting of zirconium (Zr), yttrium (Y), tantalum (Ta), lanthanum (La), cerium (Ce), titanium (Ti), hafnium (Hf), and magnesium (Mg). The switching layer 40 contains, for example, at least one oxide selected from a group consisting of zirconium oxide, yttrium oxide, tantalum oxide, lanthanum oxide, cerium oxide, titanium oxide, hafnium oxide, and magnesium oxide. More preferably, the switching layer 40 contains an oxide of the first element, which is at least one element selected from a group consisting of zirconium (Zr), yttrium (Y), lanthanum (La), and cerium (Ce). More preferably, the switching layer 40 contains at least one oxide selected from a group consisting of zirconium oxide, yttrium oxide, lanthanum oxide, and cerium oxide.

Whether or not the switching layer 40 contains an oxide of the first element can be determined by using, for example, X-ray photoelectron spectroscopy (XPS) or electron energy loss spectroscopy (EELS).

The ratio of the atomic concentration of oxygen (O) to the atomic concentration of the first element in the switching layer 40 is, for example, equal to or more than 0.5 and equal to or less than 4.0. More preferably, the ratio of the atomic concentration of oxygen (O) to the atomic concentration of the first element in the switching layer 40 is equal to or more than 0.5 and equal to or less than 3.0.

The switching layer 40 contains a chalcogenide. The chalcogenide is a compound of a second element and a third element. The second element is at least one element selected from a group consisting of zinc (Zn), tin (Sn), gallium (Ga), indium (In), and bismuth (Bi). The third element is at least one element selected from a group consisting of tellurium (Te), sulfur (S), and selenium (Se). The switching layer 40 contains a chalcogenide of the second element. The switching layer 40 contains, for example, at least one chalcogenide selected from a group consisting of zinc telluride, tin telluride, gallium telluride, indium telluride, bismuth telluride, zinc sulfide, tin sulfide, gallium sulfide, indium sulfide, bismuth sulfide, zinc selenide, tin selenide, gallium selenide, indium selenide, and bismuth selenide. The third element is more preferably tellurium (Te), and the switching layer 40 more preferably contains at least one chalcogenide selected from a group consisting of zinc telluride, tin telluride, gallium telluride, indium telluride, and bismuth telluride. Since telluride has a smaller bandgap than sulfide and selenide, the write voltage can be relatively reduced. Therefore, telluride has an advantage of being able to suppress characteristic fluctuations, such as fluctuations in half-select leakage current and fluctuations in on-current, when writing is repeated.

Whether or not the switching layer 40 contains a chalcogenide of the second element can be determined by using, for example, X-ray absorption fine structure (XAFS), Raman spectroscopy (Raman), or electron energy loss spectroscopy (EELS).

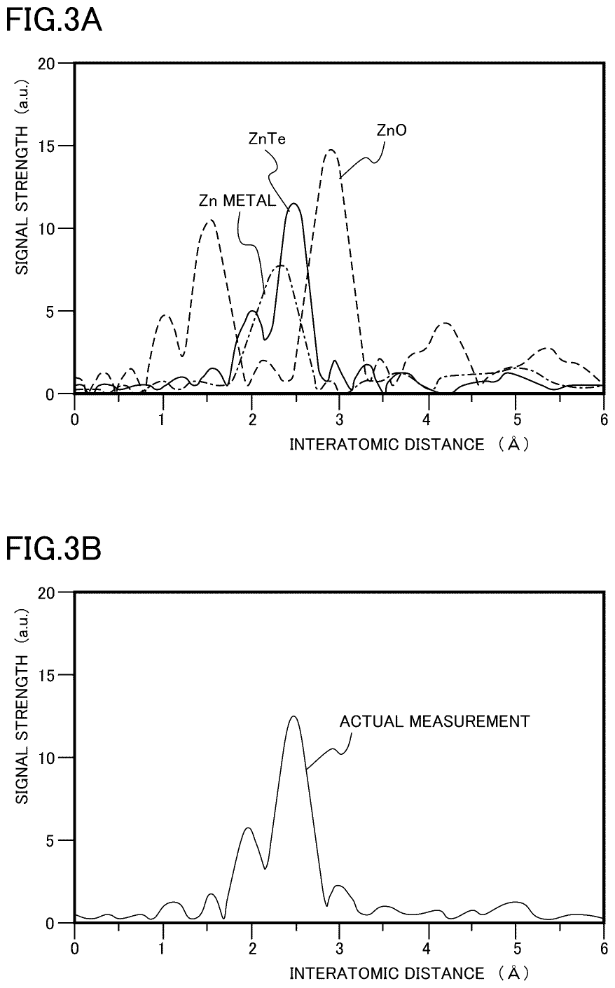

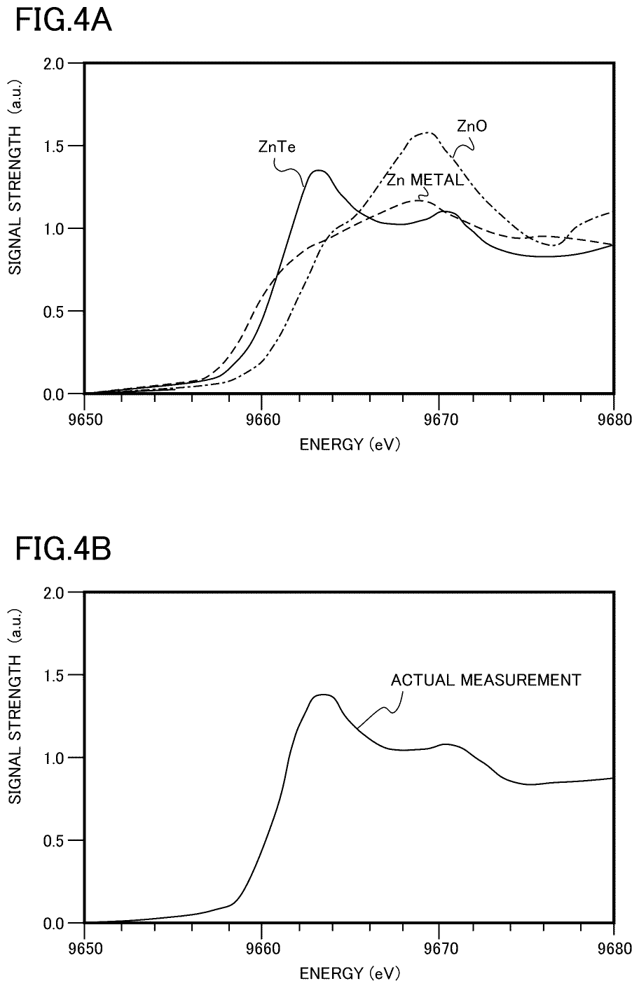

FIGS. 3A, 3B, 4A, and 4B are diagrams showing analysis results of the memory device according to the first embodiment. FIGS. 3A, 3B, 4A, and 4B show the analysis results of the switching layer 40 by XAFS in a case where the first element is zirconium (Zr), the second element is zinc (Zn), and the third element is tellurium (Te).

FIGS. 3A and 3B show the measurement results of the interatomic distance focusing on zinc (Zn). In FIGS. 3A and 3B, the horizontal axis indicates the interatomic distance, and the vertical axis indicates the signal strength. FIG. 3A shows the waveform of a standard sample, and FIG. 3B shows the measured waveform of the switching layer 40.

A comparison of the waveforms shown in FIGS. 3A and 3B reveals that the measured waveform is a waveform corresponding to zinc telluride (ZnTe). For example, in FIG. 3B, there is a peak at about 2.5 Å (Angstroms). This corresponds to a zinc telluride (ZnTe) peak in FIG. 3A. Therefore, it can be seen that the switching layer 40 contains zinc telluride.

FIGS. 4A and 4B show the measurement results of absorption spectra focusing on zinc (Zn). In FIGS. 4A and 4B, the horizontal axis indicates energy, and the vertical axis indicates the signal strength. FIG. 4A shows the waveform of a standard sample, and FIG. 4B shows the measured waveform of the switching layer 40.

A comparison of the waveforms shown in FIGS. 4A and 4B reveals that the measured waveform is a waveform corresponding to zinc telluride (ZnTe). For example, in FIG. 4B, there is a peak at about 9663 eV. This corresponds to a zinc telluride (ZnTe) peak in FIG. 4A. Therefore, it can be seen that the switching layer 40 contains zinc telluride. In addition, for example, the presence of zinc telluride (ZnTe) may be checked from a peak appearing between about 1020 eV and about 1050 eV. In addition, the peak at about 9663 eV corresponds to the K edge of zinc (Zn), and the peak from about 1020 eV to about 1050 eV corresponds to the L edge of zinc (Zn).

In addition, although FIGS. 3A, 3B, 4A, and 4B show examples of measurements by XAFS using X-rays as incident light, EELS using an electron beam as incident light based on the same measurement principle as XAFS can also be used to perform measurements similar to XAFS.

The oxide and chalcogenide described above are, for example, main components of the switching layer 40. The fact that the oxide and chalcogenide described above are the main components of the switching layer 40 means that there is no material having a higher mole fraction than the oxide or chalcogenide described above among the materials contained in the switching layer 40.

The sum of the atomic concentrations of the first element, the second element, the third element, and oxygen (O) in the switching layer 40 is, for example, equal to or more than 90%.

The switching layer 40 contains, for example, a mixture of the oxide and chalcogenide described above. The oxide and chalcogenide described above are present in the switching layer 40, for example, in a mixed state.

The ratio of the sum of the atomic concentrations of the first element and oxygen (O) to the sum of the atomic concentrations of the first element, the second element, the third element, and oxygen (O) in the switching layer 40 is, for example, equal to or more than 3% and equal to or less than 97%. For example, when the first element is zirconium (Zr), the second element is zinc (Zn), and the third element is tellurium (Te), the ratio ((Zr+O)/(Zr+Zn+Te+O)) of the sum of the atomic concentrations of zirconium (Zr) and oxygen (O) to the sum of the atomic concentrations of zirconium (Zr), zinc (Zn), tellurium (Te), and oxygen (O) in the switching layer 40 is equal to or more than 3% and equal to or less than 97%.

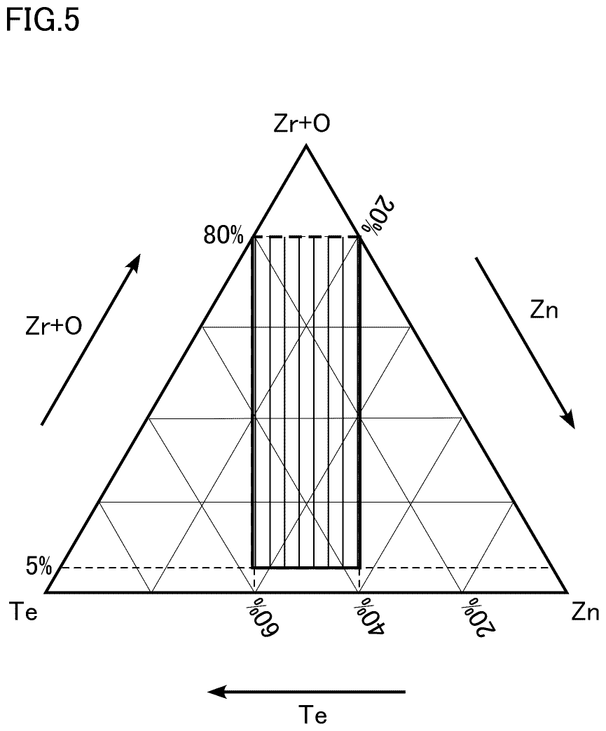

FIG. 5 is a diagram showing an example of a chemical composition of a switching layer in the memory device according to the first embodiment. FIG. 5 illustrates a chemical composition on a triangular diagram when the first element is zirconium (Zr), the second element is zinc (Zn), and the third element is tellurium (Te). The triangular diagram has “the sum of zirconium (Zr) and oxygen (O)”, “zinc (Zn)”, and “tellurium (Te)” in the switching layer 40 as vertices.

The ratio of the sum of the atomic concentrations of the first element and oxygen (O) to the sum of the atomic concentrations of the first element, the second element, the third element, and oxygen (O) in the switching layer 40 is, for example, equal to or more than 5% and less than 80%. In addition, the ratio of the absolute value of the difference between the atomic concentration of the third element and the atomic concentration of the second element to the sum of the atomic concentrations of the first element, the second element, the third element, and oxygen (O) is, for example, equal to or less than 20%. The above composition range when the first element is zirconium (Zr), the second element is zinc (Zn), and the third element is tellurium (Te) is the composition range of a hatched area on the triangular diagram of FIG. 5.

The ratio (Zr+O)/(Zr+Zn+Te+O) of the sum of the atomic concentrations of zirconium (Zr) and oxygen (O) to the sum of the atomic concentrations of zirconium (Zr), zinc (Zn), tellurium (Te), and oxygen (O) is, for example, equal to or more than 5% and less than 80%. Then, for example, the ratio (|Te−Zn|)/(Zr+Zn+Te+O) of the absolute value of the difference between the atomic concentration of tellurium (Te) and the atomic concentration of zinc (Zn) to the sum of the atomic concentrations of zirconium (Zr), zinc (Zn), tellurium (Te), and oxygen (O) is equal to or less than 20%.

The atomic concentration of the third element in the switching layer 40 is, for example, higher than the atomic concentration of the second element. For example, when the second element is zinc (Zn) and the third element is tellurium (Te), the atomic concentration of tellurium (Te) in the switching layer 40 is higher than the atomic concentration of zinc (Zn).

The switching layer 40 contains, for example, a chalcogenide formed by combining the second element and the third element and a surplus third element that does not form a chalcogenide. For example, when the second element is zinc (Zn) and the third element is tellurium (Te), zinc telluride and surplus tellurium (Te) coexist in the switching layer 40.

For example, at least a part of the oxide contained in the switching layer 40 is crystalline. Whether or not at least a part of the oxide contained in the switching layer 40 is crystalline can be determined by using, for example, an electron diffraction method. In addition, a part of the chalcogenide contained in the switching layer 40 may be crystalline.

The switching layer 40 contains, for example, a fourth element that is at least one element selected from a group consisting of carbon (C), boron (B), nitrogen (N), germanium (Ge), silicon (Si), and aluminum (Al). The atomic concentration of the fourth element contained in the switching layer 40 is, for example, equal to or more than 5% and equal to or less than 20%.

The switching layer 40 can be formed by using a sputtering method, for example. The switching layer 40 containing the oxide of the first element and the chalcogenide of the second element can be formed by using, for example, a co-sputtering method using a target formed of the oxide of the first element and a target formed of the chalcogenide of the second element. In addition, the switching layer 40 can be formed by using, for example, a sputtering method using a target formed of a mixture of the oxide of the first element and the chalcogenide of the second element.

The variable resistance layer 50 is provided between the intermediate electrode 30 and the upper electrode 20. The variable resistance layer 50 includes the fixed layer 51, the tunnel layer 52, and the free layer 53. The variable resistance layer 50 includes a magnetic tunnel junction formed by the fixed layer 51, the tunnel layer 52, and the free layer 53.

The variable resistance layer 50 has a function of storing data by resistance change. The variable resistance layer 50 has, for example, a characteristic that the electrical resistance changes with the application of a predetermined voltage.

The fixed layer 51 is a ferromagnetic material. In the fixed layer 51, the magnetization direction does not change with respect to a predetermined write voltage, and the magnetization direction is fixed in a specific direction.

The tunnel layer 52 is an insulator. Electrons pass through the tunnel layer 52 by the tunnel effect.

The free layer 53 is a ferromagnetic material. In the free layer 53, the magnetization direction changes with respect to a predetermined write voltage. The magnetization direction of the free layer 53 can be parallel to the magnetization direction of the fixed layer 51 or can be antiparallel to the magnetization direction of the fixed layer 51. For example, by applying a voltage between the intermediate electrode 30 and the upper electrode 20 so that a current flow between the intermediate electrode 30 and the upper electrode 20, the magnetization direction of the free layer 53 can be changed.

By changing the magnetization direction of the free layer 53, the electrical resistance of the variable resistance layer 50 changes. When the magnetization direction of the free layer 53 is antiparallel to the magnetization direction of the fixed layer 51, a current hardly flows to become a high resistance state. On the other hand, when the magnetization direction of the free layer 53 is parallel to the magnetization direction of the fixed layer 51, a current flows easily to become a low resistance state. In addition, the arrangement of the fixed layer 51 and the free layer 53 may be reversed. That is, the intermediate electrode 30, the free layer 53, the tunnel layer 52, the fixed layer 51, and the upper electrode 20 may be stacked in this order.

Next, the function and effect of the memory device according to the first embodiment will be described.

In the memory device according to the first embodiment, the resistance of the variable resistance layer 50 is changed by changing the magnetization direction of the free layer 53 as described above. When the magnetization direction of the free layer 53 is antiparallel to the magnetization direction of the fixed layer 51, a current hardly flows to become a high resistance state. On the other hand, when the magnetization direction of the free layer 53 is parallel to the magnetization direction of the fixed layer 51, a current flows easily to become a low resistance state.

For example, the high resistance state of the variable resistance layer 50 is defined as data “1”, and the low resistance state of the variable resistance layer 50 is defined as data “0”. Since the memory cell MC can maintain different resistance states, it is possible to store 1-bit data of “0” and “1”. Writing to one memory cell MC is performed by applying a voltage between the bit line 103 and the word line 102 connected to the memory cell MC so that a current flows between the bit line 103 and the word line 102 connected to the memory cell MC.

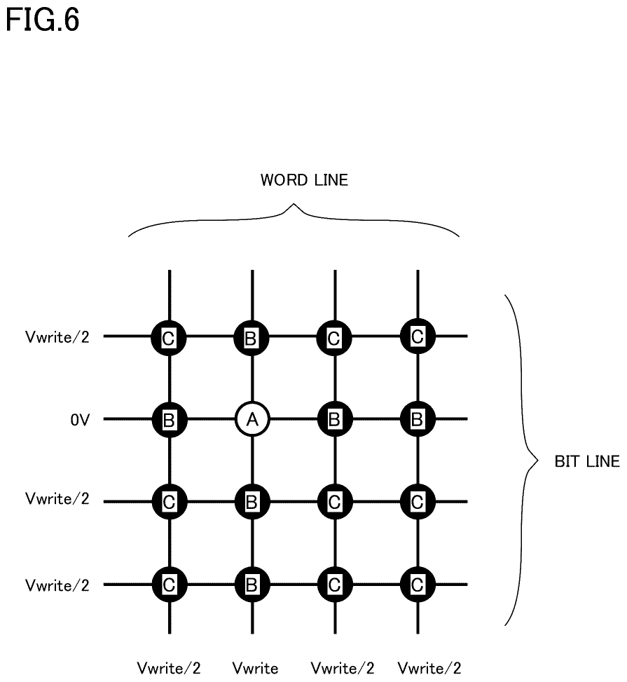

FIG. 6 is an explanatory diagram of a problem of the memory device according to the first embodiment. FIG. 6 shows a voltage applied to the memory cell MC when one memory cell MC in the memory cell array is selected for a write operation. The intersection of word lines and bit lines represents each memory cell MC.

The selected memory cell MC is a memory cell A (selected cell). A write voltage Vwrite is applied to the word line connected to the memory cell A. In addition, 0 V is applied to the bit line connected to the memory cell A.

Hereinafter, a case in which half (Vwrite/2) the write voltage is applied to the word lines and bit lines that are not connected to the memory cell A will be described as an example.

A voltage applied to memory cells C (non-selected cells) connected to the word lines and bit lines that are not connected to the memory cell A is 0 V. That is, no voltage is applied.

On the other hand, half (Vwrite/2) the write voltage Vwrite is applied to memory cells B (half-selected cells) connected to the word lines or bit lines connected to the memory cell A. Therefore, a half-select leakage current flows through the memory cell B (half-selected cell).

In addition, as an application method other than those described above, a method may be used in which half the write voltage (Vwrite/2) is applied to the word line connected to the memory cell A, a negative voltage (−Vwrite/2) of half the write voltage is applied to the bit line, and 0 V is applied to the word line and the bit line that are not connected to the memory cell A.

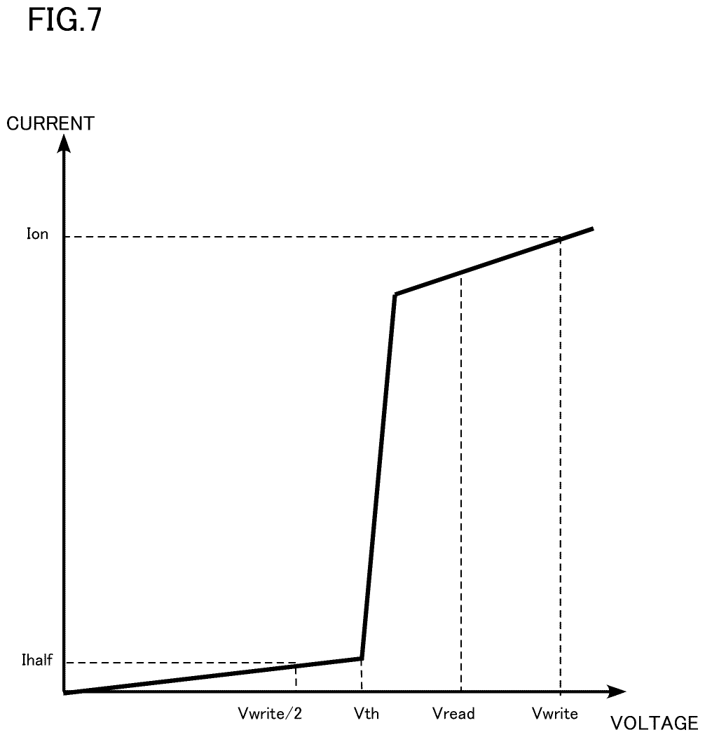

FIG. 7 is an explanatory diagram of the current-voltage characteristics of a switching element in the first embodiment. The horizontal axis indicates a voltage applied to the switching element, and the vertical axis indicates a current flowing through the switching element.

The switching element has a nonlinear current-voltage characteristic that a current increases abruptly at a threshold voltage Vth. The threshold voltage Vth is, for example, equal to or more than 0.5 V and equal to or less than 3 V.

The write voltage Vwrite is set such that the write voltage Vwrite is higher than the threshold voltage Vth and half (Vwrite/2) the write voltage Vwrite is lower than the threshold voltage Vth. The current flowing through the switching element when the write voltage Vwrite is applied is an on-current (Ion in FIG. 7). The current flowing through the switching element when half (Vwrite/2) the write voltage Vwrite is applied is a half-select leakage current (Ihalf in FIG. 7).

In addition, a read voltage Vread of the memory cell MC is set to a voltage higher than the threshold voltage Vth and lower than the write voltage Vwrite, as shown in FIG. 7, for example. Therefore, the half-select leakage current flowing through the half-selected cell can also be suppressed when reading the memory cell MC.

If the half-select leakage current is large, for example, the power consumption of the chip increases. In addition, for example, a voltage drop in the wiring increases and accordingly, a sufficiently high voltage is not applied to the selected cell. As a result, an operation for writing to the memory cell MC becomes unstable. In addition, if the on-current is small, for example, the current flowing through the selected cell is insufficient, resulting in insufficient writing to the memory cell MC. Therefore, as the current-voltage characteristics of the switching element, it is required to have both a low half-select leakage current and a high on-current.

In addition, high reliability is required for the current-voltage characteristics of the switching element. That is, it is required to realize high reliability by suppressing characteristic fluctuations, such as fluctuations in half-select leakage current and fluctuations in on-current, when repeating data writing to the memory cell MC.

For example, as a switching element of a first comparative example, a switching element is considered in which a switching layer is formed of only the chalcogenide of the second element and does not contain the oxide of the first element. The switching element of the first comparative example has problems such as a high half-select leakage current and a large characteristic fluctuation when repeating data writing to the memory cell MC.

One of the causes of the above problems occurring in the switching element of the first comparative example is considered to be crystallization of amorphous chalcogenide. For example, it is thought that due to the crystallization of chalcogenide, the interatomic distance decreases as the density increases and accordingly, the leakage current increases. In addition, for example, it is thought that the crystal grain boundary of chalcogenide increases the leakage current. In addition, for example, it is thought that film peeling between the switching layer and the electrode is caused by the stress due to the crystallization of the chalcogenide.

For example, as a switching element of a second comparative example, a switching element is considered in which a switching layer is formed of only the oxide of the first element and the second element and does not contain the chalcogenide of the second element. The switching element of the second comparative example has a problem that characteristic fluctuations when repeating data writing to the memory cell MC are large.

One of the causes of the above problem occurring in the switching element of the second comparative example is considered to be aggregation of the second element in the switching layer when writing is repeated. For example, it is thought that the aggregation of the second element forms a leakage current path.

The switching layer 40 of the switching element according to the first embodiment contains an oxide of the first element and a chalcogenide of the second element. Since the switching layer 40 contains the oxide of the first element and the chalcogenide of the second element, a low half-select leakage current and suppression of characteristic fluctuations can be realized.

The reason why the low half-select leakage current of the switching element and the suppression of characteristic fluctuations can be realized in the first embodiment is considered to be that the switching layer 40 contains the oxide of the first element and the chalcogenide of the second element and accordingly, crystallization of the chalcogenide of the second element can be suppressed. That is, it is thought that the amorphous state of the chalcogenide of the second element is stabilized. In particular, in a region of the switching layer 40 where the proportion of the chalcogenide of the second element is large, the suppression of the crystallization of the chalcogenide of the second element becomes a dominant factor. Therefore, it is thought that the excellent characteristics of the switching element can be realized.

In addition, the reason why the low half-select leakage current of the switching element and the suppression of characteristic fluctuations can be realized in the first embodiment is considered to be that the switching layer 40 contains the oxide of the first element and the chalcogenide of the second element and accordingly, aggregation of the second element can be suppressed. That is, in the switching layer 40, the second element is contained as a chalcogenide of the second element having a higher melting point than the single second element. Therefore, it is thought that diffusion of the second element is suppressed and accordingly, aggregation of the second element can be suppressed. In particular, in a region of the switching layer 40 where the proportion of the oxide of the first element is large, the suppression of the aggregation of the second element becomes a dominant factor. Therefore, it is thought that the excellent characteristics of the switching element can be realized.

The ratio of the atomic concentration of oxygen (O) to the atomic concentration of the first element in the switching layer 40 is preferably equal to or more than 0.5 and equal to or less than 4.0, more preferably equal to or more than 0.5 and equal to or less than 3.0. Satisfying the above range further improves the characteristics of the switching element.

For example, the ratio of the sum of the atomic concentrations of the first element and oxygen (O) to the sum of the atomic concentrations of the first element, the second element, the third element, and oxygen (O) in the switching layer 40 is preferably equal to or more than 3% and equal to or less than 97%, more preferably equal to or more than 5% and less than 80%, even more preferably equal to or more than 10% and less than 60%, and most preferably equal to or more than 20% and less than 50%. Satisfying the above range further improves the characteristics of the switching element.

In addition, it is preferable that the ratio of the sum of the atomic concentrations of the first element and oxygen (O) to the sum of the atomic concentrations of the first element, the second element, the third element, and oxygen (O) in the switching layer 40 is, for example, equal to or more than 5% and less than 80%. In addition, the ratio of the absolute value of the difference between the atomic concentration of the third element and the atomic concentration of the second element to the sum of the atomic concentrations of the first element, the second element, the third element, and oxygen (O) is preferably equal to or less than 20%, more preferably equal to or less than 10%, and even more preferably equal to or less than 5%. Satisfying the above range further improves the characteristics of the switching element.

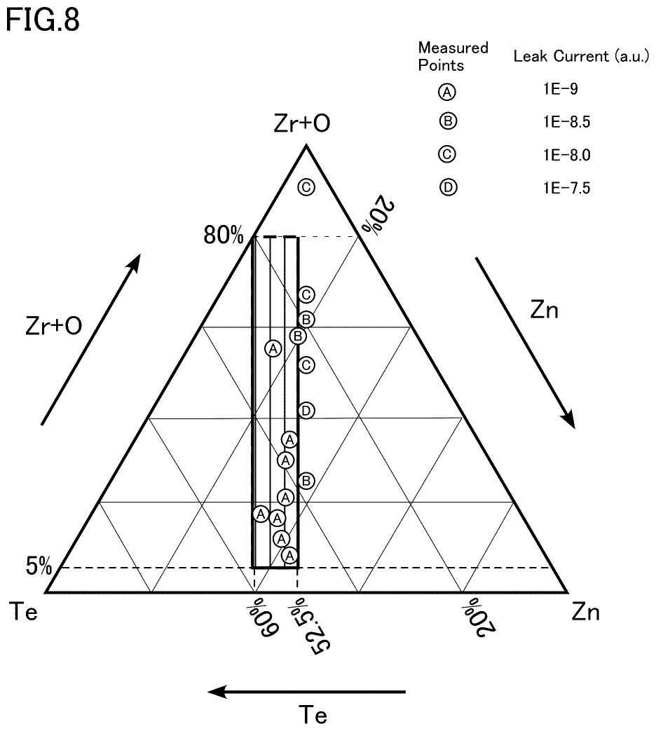

FIG. 8 is an explanatory diagram of the function and effect of the memory device according to the first embodiment. FIG. 8 is a diagram showing the relationship between the chemical composition of the switching layer 40 and the half-select leakage current. FIG. 8 shows measured data on a triangular diagram when the first element is zirconium (Zr), the second element is zinc (Zn), and the third element is tellurium (Te). The triangular diagram has “the sum of zirconium (Zr) and oxygen (O)”, “zinc (Zn)”, and “tellurium (Te)” in the switching layer 40 as vertices.

A measurement point A, a measurement point B, a measurement point C, and a measurement point D are distinguished by the amount of measured half-select leakage current. The half-select leakage current at the measurement point A is the smallest, and the half-select leakage current at the measurement point D is the largest.

From the results shown in FIG. 8, from the viewpoint of reducing the half-select leakage current, it is preferable that the switching layer 40 has the chemical composition of the hatched region on the triangular diagram. That is, it is preferable that, in the switching layer 40, the atomic concentration of tellurium (Te) is higher than the atomic concentration of zinc (Zn), the ratio of the sum of the atomic concentrations of zirconium (Zr) and oxygen (O) to the sum of the atomic concentrations of zirconium (Zr), zinc (Zn), tellurium (Te), and oxygen (O) is equal to or more than 5% and less than 80%, and the ratio of the difference between the atomic concentration of tellurium (Te) and the atomic concentration of zinc (Zn) to the sum of the atomic concentrations of zirconium (Zr), zinc (Zn), tellurium (Te), and oxygen (O) is equal to or more than 5% and equal to or less than 20%.

Generalizing the above findings, it is preferable that, in the switching layer 40, the atomic concentration of the third element is higher than the atomic concentration of the second element, the ratio of the sum of the atomic concentrations of the first element and oxygen to the sum of the atomic concentrations of the first element, the second element, the third element, and oxygen (O) is equal to or more than 5% and less than 80%, and the ratio of the difference between the atomic concentration of the third element and the atomic concentration of the second element to the sum of the atomic concentrations of the first element, the second element, the third element, and oxygen (O) is equal to or more than 5% and equal to or less than 20%. Since the first element, the second element, and the third element are elements having properties similar to those of zirconium (Zr), zinc (Zn), and tellurium (Te), respectively, it is thought that the above findings regarding zirconium (Zr), zinc (Zn), and tellurium (Te) can be generalized.

It is preferable that the atomic concentration of the third element in the switching layer 40 is higher than the atomic concentration of the second element. Since the atomic concentration of the third element is higher than the atomic concentration of the second element, the characteristics of the switching element are further improved.

From the viewpoint of further improving the characteristics of the switching element, it is preferable that the switching layer 40 contains a fourth element that is at least one element selected from a group consisting of carbon (C), boron (B), nitrogen (N), germanium (Ge), silicon (Si), and aluminum (Al). From the viewpoint of further improving the characteristics of the switching element, it is preferable that the atomic concentration of the fourth element contained in the switching layer 40 is equal to or more than 5% and equal to or less than 20%.

From the viewpoint of further improving the characteristics of the switching element, it is preferable that at least a part of the oxide of the first element contained in the switching layer 40 is crystalline. It is thought that diffusion of the first element is suppressed by making at least a part of the oxide of the first element crystalline and accordingly, an increase in leakage current due to the separated first element can be suppressed.

### First Modification Example

A memory device according to a first modification example of the first embodiment is different from the memory device according to the first embodiment in that a first conductive layer includes a first portion and a second portion and the first portion contains at least one element selected from hafnium (Hf), aluminum (Al), magnesium (Mg), zirconium (Zr), and titanium (Ti).

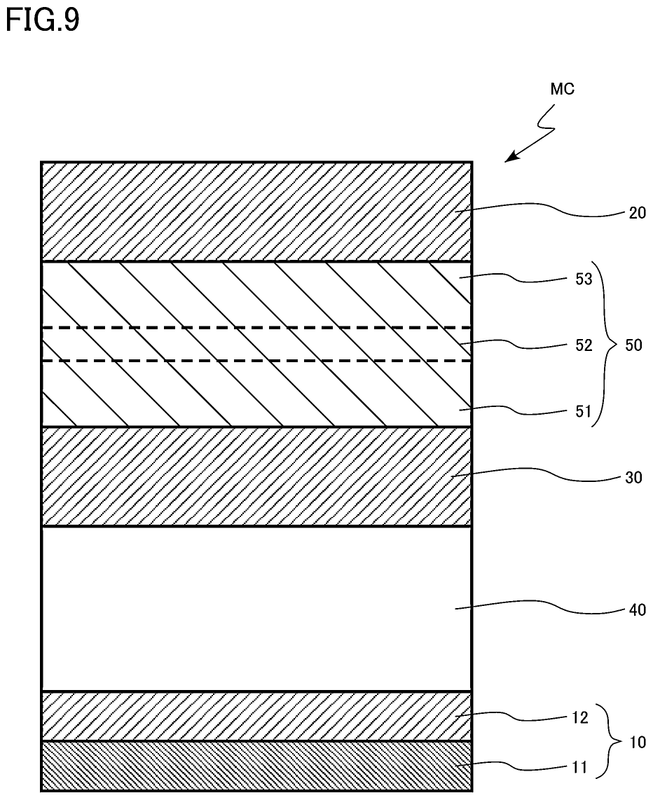

FIG. 9 is a schematic cross-sectional view of a memory cell in the memory device according to the first modification example of the first embodiment. FIG. 9 is a diagram corresponding to FIG. 2 of the first embodiment.

The lower electrode 10 includes a first portion 11 and a second portion 12. The second portion 12 is provided between the first portion 11 and the switching layer 40.

The first portion 11 contains at least one element selected from hafnium (Hf), aluminum (Al), magnesium (Mg), zirconium (Zr), and titanium (Ti). The first portion 11 contains, for example, borides of the above elements. The first portion 11 contains, for example, at least one material selected from a group consisting of hafnium, hafnium boride, magnesium aluminum boride, zirconium, zirconium boride, and titanium boride.

The second portion 12 contains, for example, at least one material selected from a group consisting of carbon, carbon nitride, tungsten, tungsten carbide, and tungsten nitride.

In the memory device according to the first modification example of the first embodiment, since the first portion 11 of the lower electrode 10 contains at least one element selected from hafnium (Hf), aluminum (Al), magnesium (Mg), zirconium (Zr), and titanium (Ti), degradation of the characteristics of the variable resistance element is suppressed. In addition, since the first portion 11 is not in contact with the switching layer 40, desorption of oxygen (O) from the switching layer 40 is suppressed and accordingly, degradation of the characteristics of the switching element is suppressed.

As described above, according to the first modification example of the first embodiment, as in the first embodiment, it is possible to realize a switching element having excellent characteristics of low half-select leakage current and high reliability.

### Second Modification Example

A memory device according to a second modification example of the first embodiment is different from the memory device according to the first embodiment in that a first conductive layer includes a first portion and a second portion, the first portion contains at least one element selected from hafnium (Hf), aluminum (Al), magnesium (Mg), zirconium (Zr), and titanium (Ti), a second conductive layer contains one element selected from hafnium (Hf), aluminum (Al), magnesium (Mg), zirconium (Zr), and titanium (Ti), a third conductive layer includes a third portion and a fourth portion, and the fourth portion contains at least one element selected from hafnium (Hf), aluminum (Al), magnesium (Mg), zirconium (Zr), and titanium (Ti).

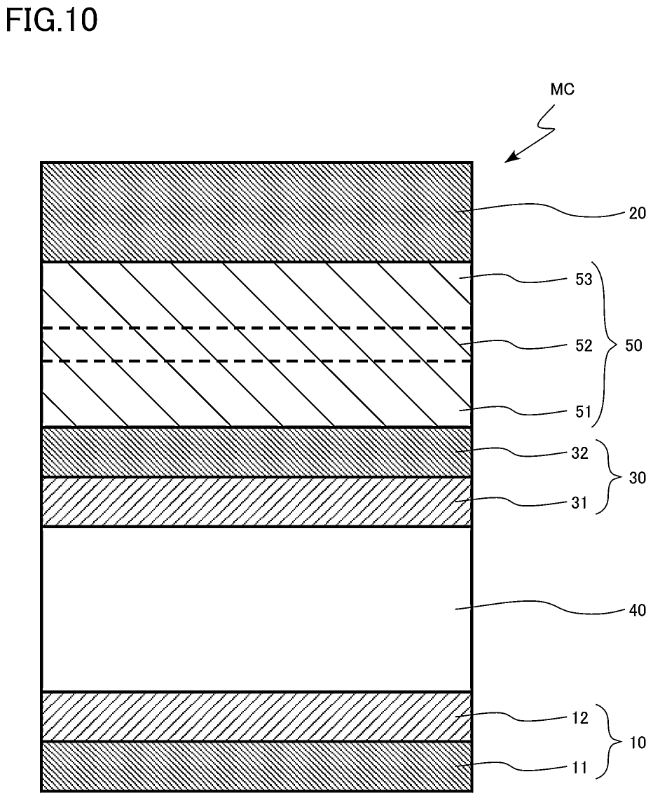

FIG. 10 is a schematic cross-sectional view of a memory cell in the memory device according to the second modification example of the first embodiment. FIG. 10 is a diagram corresponding to FIG. 2 of the first embodiment.

The lower electrode 10 includes a first portion 11 and a second portion 12. The second portion 12 is provided between the first portion 11 and the switching layer 40.

The first portion 11 contains at least one element selected from hafnium (Hf), aluminum (Al), magnesium (Mg), zirconium (Zr), and titanium (Ti). The first portion 11 contains, for example, borides of the above elements. The first portion 11 contains, for example, at least one material selected from a group consisting of hafnium, hafnium boride, magnesium aluminum boride, zirconium, zirconium boride, and titanium boride.

The second portion 12 contains, for example, at least one material selected from a group consisting of carbon, carbon nitride, tungsten, tungsten carbide, and tungsten nitride.

The upper electrode 20 contains at least one element selected from hafnium (Hf), aluminum (Al), magnesium (Mg), zirconium (Zr), and titanium (Ti). The upper electrode 20 contains, for example, borides of the above elements. The upper electrode 20 contains, for example, at least one material selected from a group consisting of hafnium, hafnium boride, magnesium aluminum boride, zirconium, zirconium boride, and titanium boride.

The intermediate electrode 30 includes a third portion 31 and a fourth portion 32. The third portion 31 is provided between the fourth portion 32 and the switching layer 40.

The third portion 31 contains, for example, at least one material selected from a group consisting of carbon, carbon nitride, tungsten, tungsten carbide, and tungsten nitride.

The fourth portion 32 contains at least one element selected from hafnium (Hf), aluminum (Al), magnesium (Mg), zirconium (Zr), and titanium (Ti). The fourth portion 32 contains, for example, borides of the above elements. The fourth portion 32 contains, for example, at least one material selected from a group consisting of hafnium, hafnium boride, magnesium aluminum boride, zirconium, zirconium boride, and titanium boride.

In the memory device according to the second modification example of the first embodiment, since the first portion 11 of the lower electrode 10, the upper electrode 20, and the fourth portion 32 of the intermediate electrode 30 contain at least one element selected from hafnium (Hf), aluminum (Al), magnesium (Mg), zirconium (Zr), and titanium (Ti), degradation of the characteristics of the variable resistance element is suppressed. In addition, since the first portion 11 of the lower electrode 10, the upper electrode 20, and the fourth portion 32 of the intermediate electrode 30 are not in contact with the switching layer 40, desorption of oxygen (O) from the switching layer 40 is suppressed and accordingly, degradation of the characteristics of the switching element is suppressed.

As described above, according to the second modification example of the first embodiment, as in the first embodiment, it is possible to realize a switching element having excellent characteristics of low half-select leakage current and high reliability.

### Third Modification Example

A memory device according to a third modification example of the first embodiment is different from the memory device according to the first embodiment in that a first conductive layer includes a first portion, a second portion, and a fifth portion, the first portion contains at least one element selected from hafnium (Hf), aluminum (Al), magnesium (Mg), zirconium (Zr), and titanium (Ti), a second conductive layer contains at least one element selected from hafnium (Hf), aluminum (Al), magnesium (Mg), zirconium (Zr), and titanium (Ti), a third conductive layer includes a third portion and a fourth portion, and the fourth portion contains at least one element selected from hafnium (Hf), aluminum (Al), magnesium (Mg), zirconium (Zr), and titanium (Ti).

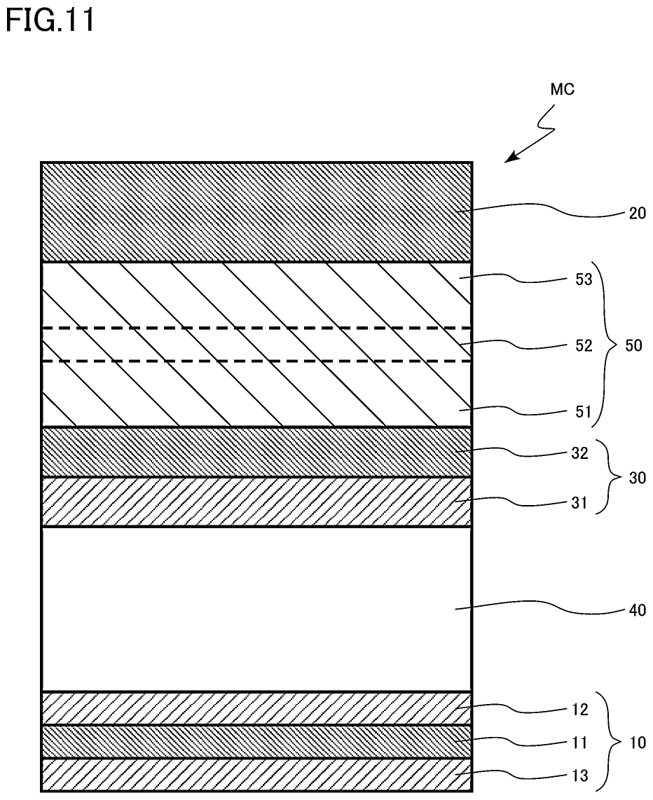

FIG. 11 is a schematic cross-sectional view of a memory cell in the memory device according to the third modification example of the first embodiment. FIG. 11 is a diagram corresponding to FIG. 2 of the first embodiment.

The lower electrode 10 includes a first portion 11, a second portion 12, and a fifth portion 13. The second portion 12 is provided between the first portion 11 and the switching layer 40. The first portion 11 is provided between the fifth portion 13 and the second portion 12.

The first portion 11 contains at least one element selected from hafnium (Hf), aluminum (Al), magnesium (Mg), zirconium (Zr), and titanium (Ti). The first portion 11 contains, for example, borides of the above elements. The first portion 11 contains, for example, at least one material selected from a group consisting of hafnium, hafnium boride, magnesium aluminum boride, zirconium, zirconium boride, and titanium boride.

The second portion 12 and the fifth portion 13 contain, for example, at least one material selected from a group consisting of carbon, carbon nitride, tungsten, tungsten carbide, and tungsten nitride.

The upper electrode 20 contains at least one element selected from hafnium (Hf), aluminum (Al), magnesium (Mg), zirconium (Zr), and titanium (Ti). The upper electrode 20 contains, for example, borides of the above elements. The upper electrode 20 contains, for example, at least one material selected from a group consisting of hafnium, hafnium boride, magnesium aluminum boride, zirconium, zirconium boride, and titanium boride.

The intermediate electrode 30 includes a third portion 31 and a fourth portion 32. The third portion 31 is provided between the fourth portion 32 and the switching layer 40.

The third portion 31 contains, for example, at least one material selected from a group consisting of carbon, carbon nitride, tungsten, tungsten carbide, and tungsten nitride.

The fourth portion 32 contains at least one element selected from hafnium (Hf), aluminum (Al), magnesium (Mg), zirconium (Zr), and titanium (Ti). The fourth portion 32 contains, for example, borides of the above elements. The fourth portion 32 contains, for example, at least one material selected from a group consisting of hafnium, hafnium boride, magnesium aluminum boride, zirconium, zirconium boride, and titanium boride.

In the memory device according to the third modification example of the first embodiment, since the first portion 11 of the lower electrode 10, the upper electrode 20, and the fourth portion 32 of the intermediate electrode 30 contain at least one element selected from hafnium (Hf), aluminum (Al), magnesium (Mg), zirconium (Zr), and titanium (Ti), degradation of the characteristics of the variable resistance element is suppressed. In addition, since the first portion 11 of the lower electrode 10, the upper electrode 20, and the fourth portion 32 of the intermediate electrode 30 are not in contact with the switching layer 40, desorption of oxygen (O) from the switching layer 40 is suppressed and accordingly, degradation of the characteristics of the switching element is suppressed.

As described above, according to the third modification example of the first embodiment, as in the first embodiment, it is possible to realize a switching element having excellent characteristics of low half-select leakage current and high reliability.

According to the first embodiment and its modification examples, it is possible to realize a switching element having excellent characteristics of low half-select leakage current and high reliability. Therefore, according to the first embodiment and its modification examples, it is possible to realize a memory device having a switching element with excellent characteristics.

### Second Embodiment

A memory device according to a second embodiment is different from the memory device according to the first embodiment in that the memory device according to the second embodiment is a resistive RAM (ReRAM). Hereinafter, the description of a part of the content overlapping the first embodiment will be omitted.

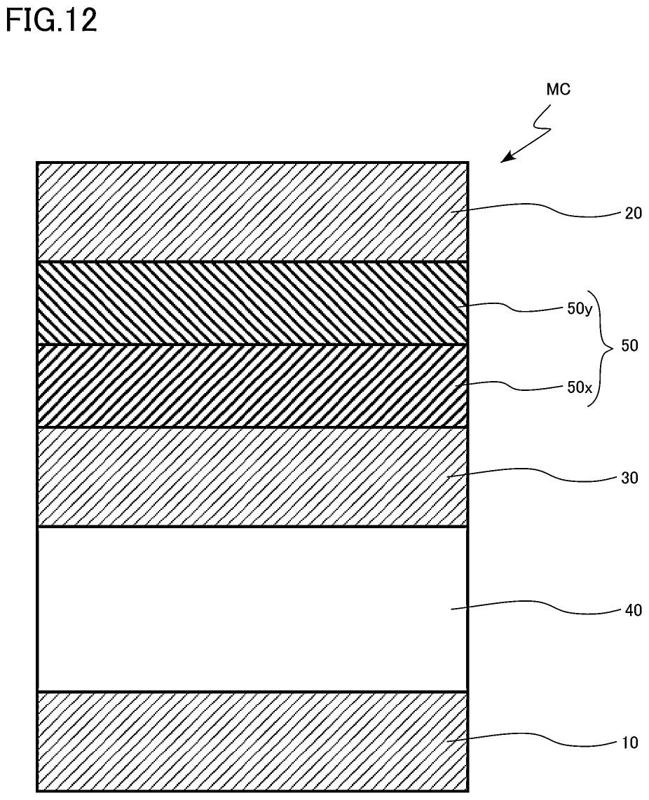

FIG. 12 is a schematic cross-sectional view of a memory cell in the memory device according to the second embodiment. FIG. 12 shows a cross section of one memory cell MC indicated by, for example, a dotted circle in the memory cell array 100 of FIG. 1.

As shown in FIG. 12, the memory cell MC includes a lower electrode 10, an upper electrode 20, an intermediate electrode 30, a switching layer 40, and a variable resistance layer 50. The variable resistance layer 50 includes a high resistance layer 50x and a low resistance layer 50y.

The lower electrode 10 is an example of the first conductive layer. The upper electrode 20 is an example of the second conductive layer. The intermediate electrode 30 is an example of the third conductive layer.

The lower electrode 10, the switching layer 40, and the intermediate electrode 30 form a switching element of the memory cell MC. The intermediate electrode 30, the variable resistance layer 50, and the upper electrode 20 form a variable resistance element of the memory cell MC.

The configuration of the switching layer 40 is similar to that in the memory device according to the first embodiment.

The variable resistance layer 50 includes the high resistance layer 50x and the low resistance layer 50y.

The high resistance layer 50x is, for example, a metal oxide. The high resistance layer 50x is, for example, an aluminum oxide, a hafnium oxide, a zirconium oxide, a tantalum oxide, or a niobium oxide.

The low resistance layer 50y is, for example, a metal oxide. The low resistance layer 50y is, for example, a titanium oxide, a niobium oxide, a tantalum oxide, or a tungsten oxide.

The variable resistance layer 50 has a function of storing data by resistance change. The variable resistance layer 50 has, for example, a characteristic that the electrical resistance changes with the application of a predetermined voltage.

By applying a voltage to the variable resistance layer 50, the variable resistance layer 50 changes from a high resistance state to a low resistance state or from a low resistance state to a high resistance state. By applying a voltage to the variable resistance layer 50, oxygen ions move between the high resistance layer 50x and the low resistance layer 50y, so that the amount of oxygen deficiency (the amount of oxygen vacancies) in the low resistance layer 50y changes. The electrical conductivity of the variable resistance layer 50 changes according to the amount of oxygen deficiency in the low resistance layer 50y. The low resistance layer 50y is a so-called vacancy modulated conductive oxide.

For example, the high resistance state is defined as data “1”, and the low resistance state is defined as data “0”. The memory cell MC can store 1-bit data of “0” and “1”.

As described above, according to the memory device of the second embodiment, as in the first embodiment, it is possible to realize a switching element having excellent characteristics of low half-select leakage current and high reliability. Therefore, according to the second embodiment, it is possible to realize a memory device having a switching element with excellent characteristics.

### Third Embodiment

A memory device according to a third embodiment includes a memory cell including a first conductive layer, a second conductive layer, and a memory layer provided between the first conductive layer and the second conductive layer. In addition, the memory layer contains an oxide of the first element, which is at least one element selected from a group consisting of zirconium (Zr), yttrium (Y), tantalum (Ta), lanthanum (La), cerium (Ce), titanium (Ti), hafnium (Hf), and magnesium (Mg), and a compound of the second element that is at least one element selected from a group consisting of zinc (Zn), tin (Sn), gallium (Ga), indium (In), and bismuth (Bi) and the third element that is at least one element selected from a group consisting of tellurium (Te), sulfur (S), and selenium (Se).

In addition, the memory device according to the third embodiment further includes a plurality of first wirings and a plurality of second wirings crossing the plurality of first wirings. In addition, the memory cell is provided in a region where one of the plurality of first wirings and one of the plurality of second wirings cross each other.

The memory device according to the third embodiment is different from the memory devices according to the first and second embodiments in that the memory cell does not include a third conductive layer and a variable resistance layer and includes the same configuration as the switching layer in the first and second embodiments as a memory layer. Hereinafter, the description of a part of the content overlapping the first or second embodiment will be omitted.

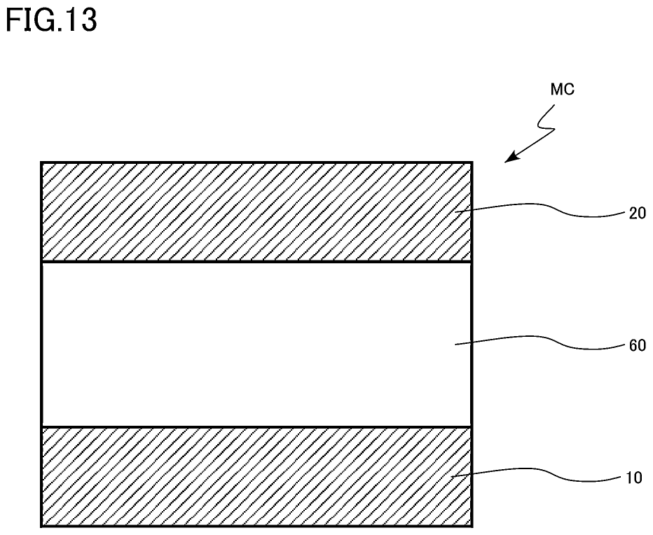

FIG. 13 is a schematic cross-sectional view of a memory cell in the memory device according to the third embodiment. FIG. 13 shows a cross section of one memory cell MC indicated by, for example, a dotted circle in the memory cell array 100 of FIG. 1.

As shown in FIG. 13, the memory cell MC includes a lower electrode 10, an upper electrode 20, and a memory layer 60.

The lower electrode 10 is an example of the first conductive layer. The upper electrode 20 is an example of the second conductive layer.

The lower electrode 10, the memory layer 60, and the upper electrode 20 form a memory element of the memory cell MC. The memory element of the memory cell MC has a switching function and an information storage function.

The memory layer 60 has a configuration similar to that of the switching layer 40 in the first and second embodiments. That is, the memory layer 60 contains an oxide of the first element, which is at least one element selected from a group consisting of zirconium (Zr), yttrium (Y), tantalum (Ta), lanthanum (La), cerium (Ce), titanium (Ti), hafnium (Hf), and magnesium (Mg), and a compound of the second element that is at least one element selected from a group consisting of zinc (Zn), tin (Sn), gallium (Ga), indium (In), and bismuth (Bi) and the third element that is at least one element selected from a group consisting of tellurium (Te), sulfur (S), and selenium (Se).

The memory layer 60 has a nonlinear current-voltage characteristic that a current increases abruptly at a specific threshold voltage. In addition, the memory layer 60 has a characteristic that the threshold voltage changes with the application of a predetermined voltage. The memory layer 60 has a characteristic that the electrical resistance changes with the application of a predetermined voltage. In the third embodiment, the high resistance state is a state in which the resistance of the memory layer 60 is relatively high at the read voltage. In addition, in the third embodiment, the low resistance state is a state in which the resistance of the memory layer 60 is relatively low at the read voltage.

The memory layer 60 has a function of suppressing an increase in half-select leakage current flowing through the half-selected cell. In addition, the memory layer 60 has a function of storing data by resistance change. The memory layer 60 is a single layer and realizes the function of the switching layer 40 and the function of the variable resistance layer 50 in the first and second embodiments.

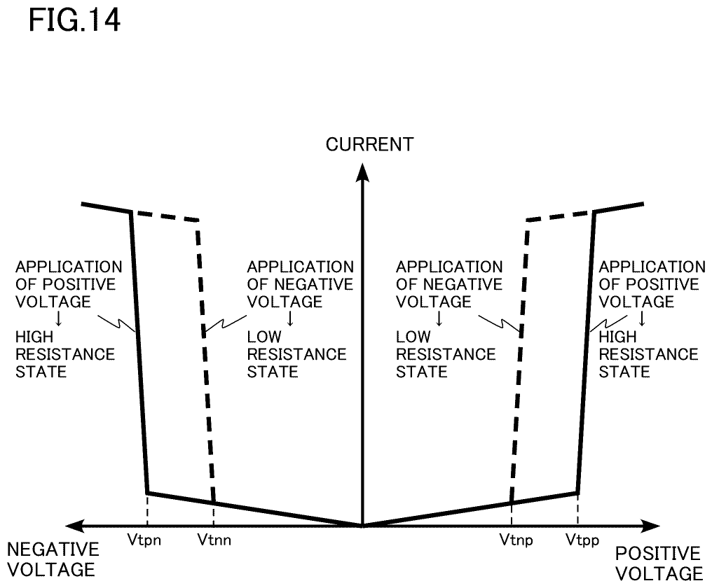

FIG. 14 is an explanatory diagram of the current-voltage characteristics of a memory element according to the third embodiment. The horizontal axis indicates a voltage applied to the memory element, and the vertical axis indicates a current flowing through the memory element. In FIG. 14, the horizontal axis indicates a voltage applied to the upper electrode 20 with the potential of the lower electrode 10 as a reference. FIG. 14 shows the current-voltage characteristics of the memory layer 60 in the third embodiment. FIG. 14 shows the current-voltage characteristics of the memory cell MC in the third embodiment.

The memory element according to the third embodiment shows different current-voltage characteristics when a predetermined positive voltage is applied to the upper electrode 20 and when a predetermined negative voltage is applied to the upper electrode 20. In FIG. 14, the solid line indicates the current-voltage characteristics when a predetermined positive voltage is applied to the upper electrode 20, and the dotted line indicates the current-voltage characteristics when a predetermined negative voltage is applied to the upper electrode 20.

When a predetermined positive voltage is applied to the upper electrode 20, the current increases abruptly at a first positive voltage side threshold voltage Vtpp on the positive voltage side. In addition, when a predetermined positive voltage is applied to the upper electrode 20, the current increases abruptly at a first negative voltage side threshold voltage Vtpn on the negative voltage side.

On the other hand, when a predetermined negative voltage is applied to the upper electrode 20, the current increases abruptly at a second positive voltage side threshold voltage Vtnp on the positive voltage side. In addition, when a predetermined negative voltage is applied to the upper electrode 20, the current increases abruptly at a second negative voltage side threshold voltage Vtnn on the negative voltage side.

The first positive voltage side threshold voltage Vtpp is higher than the second positive voltage side threshold voltage Vtnp. In addition, the first negative voltage side threshold voltage Vtpn is lower than the second negative voltage side threshold voltage Vtnn.

The memory element according to the third embodiment can have a high resistance state and a low resistance state on both the positive voltage side and the negative voltage side. When a predetermined positive voltage is applied to the upper electrode 20, a high resistance state is realized on both the positive voltage side and the negative voltage side. On the other hand, when a predetermined negative voltage is applied to the upper electrode 20, a low resistance state is realized on both the positive voltage side and the negative voltage side. Hereinafter, the high resistance state will be defined as data “1”, and the low resistance state will be defined as data “0”. The memory cell MC can store 1-bit data of “0” and “1”.

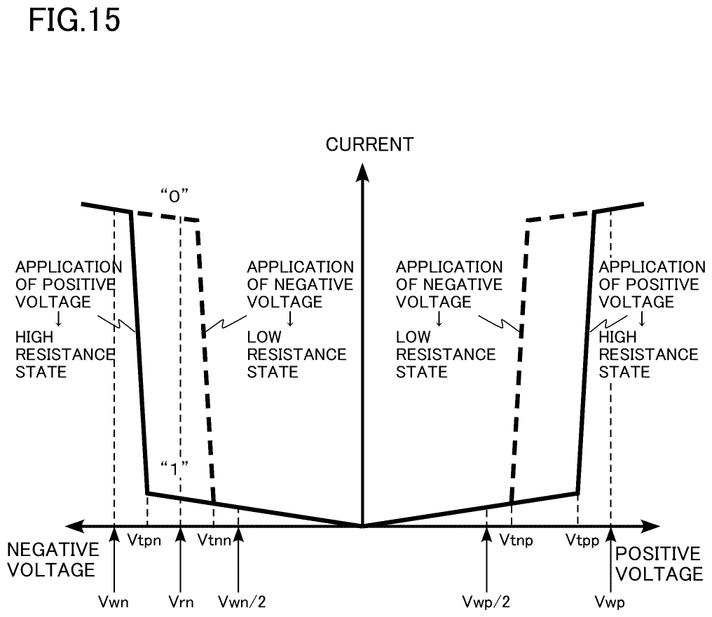

FIG. 15 is an explanatory diagram of a first operation example of the memory operation in the memory device according to the third embodiment. FIG. 15 shows a positive side write voltage Vwp, half (Vwp/2) the positive side write voltage Vwp, a negative side write voltage Vwn, half (Vwn/2) the negative side write voltage Vwn, and a negative side read voltage Vrn when performing a memory operation.

In the first operation example, the high resistance state and the low resistance state on the negative voltage side are used for the memory operation. In the first operation example, the negative side read voltage Vrn is used as a read voltage.

When writing data “1” to the selected cell, the positive side write voltage Vwp is applied to the upper electrode 20. The positive side write voltage Vwp is a voltage higher than the first positive voltage side threshold voltage Vtpp. By applying the positive side write voltage Vwp to the upper electrode 20, a high resistance state is realized on the negative voltage side, and data “1” is written to the selected cell.

When writing data “0” to the selected cell, the negative side write voltage Vwn is applied to the upper electrode 20. The negative side write voltage Vwn is a voltage lower than the first negative voltage side threshold voltage Vtpn. By applying the negative side write voltage Vwn to the upper electrode 20, a low resistance state is realized on the negative voltage side, and data “0” is written to the selected cell.

In the first operation example, when writing data “1” to the selected cell, assuming that the data stored in the selected cell is data “0”, a current flows if the positive side write voltage Vwp is higher than the second positive voltage side threshold voltage Vtnp even if the positive side write voltage Vwp is lower than the first positive voltage side threshold voltage Vtpp. For this reason, data “1” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or a potential change caused by the difference between a current that flows when data is “1” and a current that flows when data is “0”.

In addition, in the case of the first operation example, regardless of whether the data of the selected cell is data “1” or data “0”, the application of the negative side read voltage Vrn does not destroy the data. In other words, in the case of the first operation example, non-destructive reading is possible regardless of whether the data of the selected cell is data “1” or data “0”.

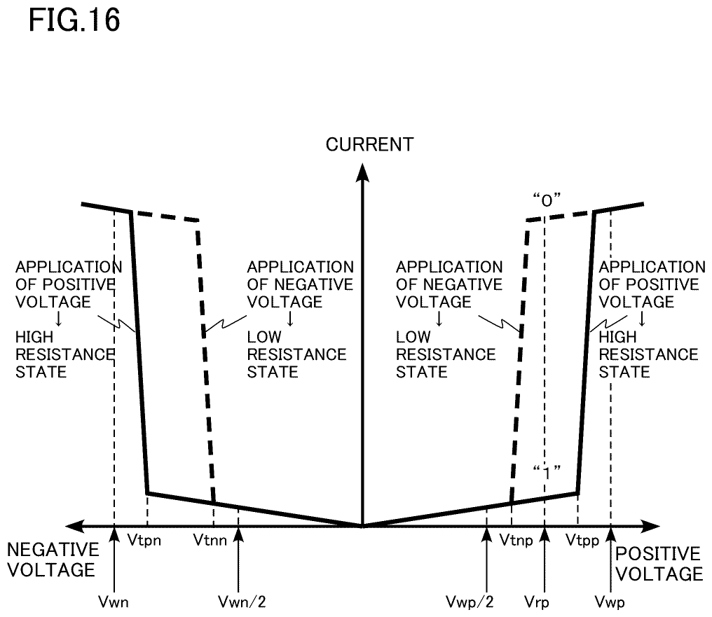

FIG. 16 is an explanatory diagram of a second operation example of the memory operation in the memory device according to the third embodiment. FIG. 16 shows a positive side write voltage Vwp, half (Vwp/2) the positive side write voltage Vwp, a negative side write voltage Vwn, half (Vwn/2) the negative side write voltage Vwn, and a positive side read voltage Vrp when performing a memory operation.

In the second operation example, the high resistance state and the low resistance state on the positive voltage side are used for the memory operation. In the second operation example, the positive side read voltage Vrp is used as a read voltage.

When writing data “1” to the selected cell, the positive side write voltage Vwp is applied to the upper electrode 20. The positive side write voltage Vwp is a voltage higher than the first positive voltage side threshold voltage Vtpp. By applying the positive side write voltage Vwp to the upper electrode 20, a high resistance state is realized on the positive voltage side, and data “1” is written to the selected cell.

When writing data “0” to the selected cell, the negative side write voltage Vwn is applied to the upper electrode 20. The negative side write voltage Vwn is a voltage lower than the first negative voltage side threshold voltage Vtpn. By applying the negative side write voltage Vwn to the upper electrode 20, a low resistance state is realized on the positive voltage side, and data “0” is written to the selected cell.

In the second operation example, when writing data “1” to the selected cell, assuming that the data stored in the selected cell is data “0”, a current flows if the positive side write voltage Vwp is higher than the second positive voltage side threshold voltage Vtnp even if the positive side write voltage Vwp is lower than the first positive voltage side threshold voltage Vtpp. For this reason, data “1” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or a potential change caused by the difference between a current that flows when data is “1” and a current that flows when data is “0”.

In addition, in the case of the second operation example, when the data of the selected cell is data “1”, the application of the positive side read voltage Vrp does not destroy the data. In other words, in the case of the second operation example, non-destructive reading is possible if the data of the selected cell is data “1”.

On the other hand, when the data of the selected cell is data “0”, the application of the positive side read voltage Vrp higher than the second positive voltage side threshold voltage Vtnp may cause a current to flow. As a result, the data of the selected cell may change to data “1”. In other words, in the case of the second operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

### First Modification Example

A memory device according to a first modification example of the third embodiment is different from the memory device according to the third embodiment in that the current-voltage characteristics of the memory elements are different.

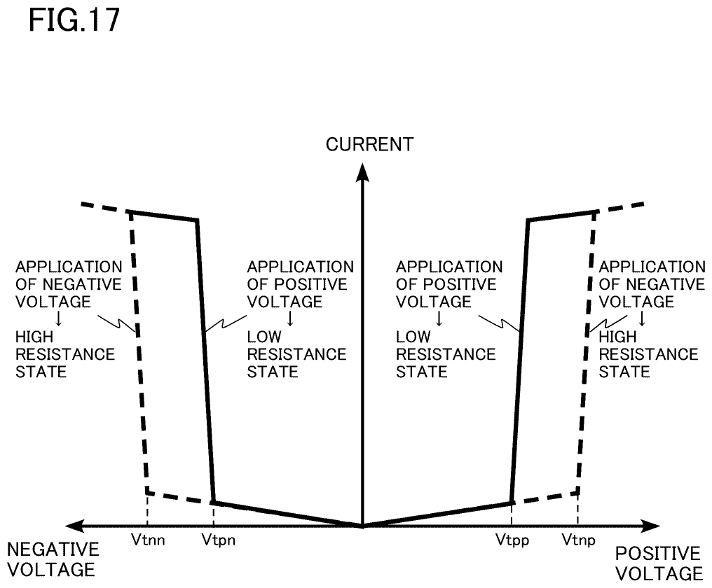

FIG. 17 is an explanatory diagram of the current-voltage characteristics of a memory element according to the first modification example of the third embodiment. The horizontal axis indicates a voltage applied to the memory element, and the vertical axis indicates a current flowing through the memory element. In FIG. 17, the horizontal axis indicates a voltage applied to the upper electrode 20 with the potential of the lower electrode 10 as a reference. FIG. 17 shows the current-voltage characteristics of the memory layer 60 in the first modification example of the third embodiment. FIG. 17 shows the current-voltage characteristics of the memory cell MC in the first modification example of the third embodiment.

The memory element according to the first modification example of the third embodiment shows different current-voltage characteristics when a predetermined positive voltage is applied to the upper electrode 20 and when a predetermined negative voltage is applied to the upper electrode 20. In FIG. 17, the solid line indicates the current-voltage characteristics when a predetermined positive voltage is applied to the upper electrode 20, and the dotted line indicates the current-voltage characteristics when a predetermined negative voltage is applied to the upper electrode 20.

When a predetermined positive voltage is applied to the upper electrode 20, the current increases abruptly at a first positive voltage side threshold voltage Vtpp on the positive voltage side. In addition, when a predetermined positive voltage is applied to the upper electrode 20, the current increases abruptly at a first negative voltage side threshold voltage Vtpn on the negative voltage side.

On the other hand, when a predetermined negative voltage is applied to the upper electrode 20, the current increases abruptly at a second positive voltage side threshold voltage Vtnp on the positive voltage side. In addition, when a predetermined negative voltage is applied to the upper electrode 20, the current increases abruptly at a second negative voltage side threshold voltage Vtnn on the negative voltage side.

The first positive voltage side threshold voltage Vtpp is lower than the second positive voltage side threshold voltage Vtnp. In addition, the first negative voltage side threshold voltage Vtpn is higher than the second negative voltage side threshold voltage Vtnn.

The memory element according to the first modification example of the third embodiment can have a high resistance state and a low resistance state on both the positive voltage side and the negative voltage side. When a predetermined positive voltage is applied to the upper electrode 20, a low resistance state is realized on both the positive voltage side and the negative voltage side. On the other hand, when a predetermined negative voltage is applied to the upper electrode 20, a high resistance state is realized on both the positive voltage side and the negative voltage side. Hereinafter, the high resistance state will be defined as data “1”, and the low resistance state will be defined as data “0”. The memory cell MC can store 1-bit data of “0” and “1”.

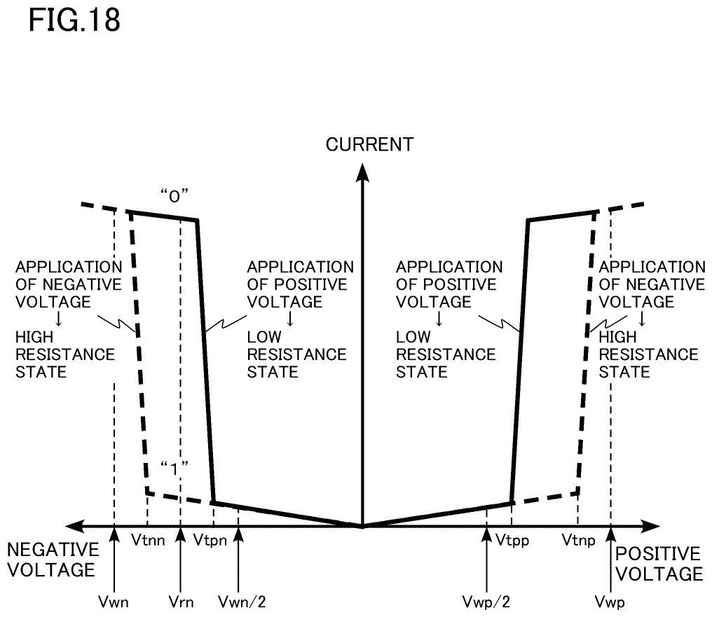

FIG. 18 is an explanatory diagram of a third operation example of the memory operation in the memory device according to the first modification example of the third embodiment. FIG. 18 shows a positive side write voltage Vwp, half (Vwp/2) the positive side write voltage Vwp, a negative side write voltage Vwn, half (Vwn/2) the negative side write voltage Vwn, and a negative side read voltage Vrn when performing a memory operation.

In the third operation example, the high resistance state and the low resistance state on the negative voltage side are used for the memory operation. In the third operation example, the negative side read voltage Vrn is used as a read voltage.

When writing data “1” to the selected cell, the negative side write voltage Vwn is applied to the upper electrode 20. The negative side write voltage Vwn is a voltage lower than the second negative voltage side threshold voltage Vtnn. By applying the negative side write voltage Vwn to the upper electrode 20, a high resistance state is realized on the negative voltage side, and data “1” is written to the selected cell.

When writing data “0” to the selected cell, the positive side write voltage Vwp is applied to the upper electrode 20. The positive side write voltage Vwp is a voltage higher than the second positive voltage side threshold voltage Vtnp. By applying the positive side write voltage Vwp to the upper electrode 20, a low resistance state is realized on the negative voltage side, and data “0” is written to the selected cell.

In the third operation example, when writing data “1” to the selected cell, assuming that the data stored in the selected cell is data “0”, a current flows if the negative side write voltage Vwn is lower than the first negative voltage side threshold voltage Vtpn even if the negative side write voltage Vwn is higher than the second negative voltage side threshold voltage Vtnn. For this reason, data “1” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or a potential change caused by the difference between a current that flows when data is “1” and a current that flows when data is “0”.

In addition, in the case of the third operation example, when the data of the selected cell is data “1”, the application of the negative side read voltage Vrn does not destroy the data. In other words, in the case of the third operation example, non-destructive reading is possible if the data of the selected cell is data “1”.

On the other hand, when the data of the selected cell is data “0”, the application of the negative side read voltage Vrn lower than the first negative voltage side threshold voltage Vtpn may cause a current to flow. As a result, the data of the selected cell may change to data “1”. In other words, in the case of the third operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

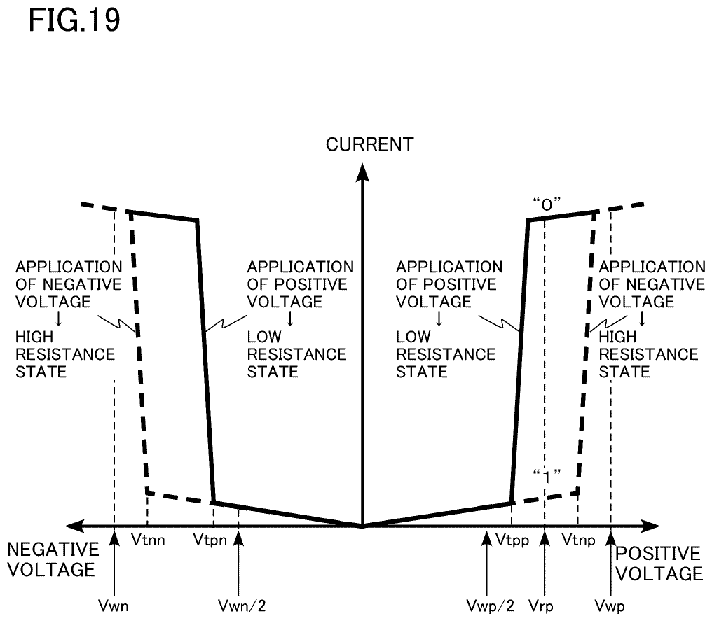

FIG. 19 is an explanatory diagram of a fourth operation example of the memory operation in the memory device according to the first modification example of the third embodiment. FIG. 19 shows a positive side write voltage Vwp, half (Vwp/2) the positive side write voltage Vwp, a negative side write voltage Vwn, half (Vwn/2) the negative side write voltage Vwn, and a positive side read voltage Vrp when performing a memory operation.

In the fourth operation example, the high resistance state and the low resistance state on the positive voltage side are used for the memory operation. In the fourth operation example, the positive side read voltage Vrp is used as a read voltage.

When writing data “1” to the selected cell, the negative side write voltage Vwn is applied to the upper electrode 20. The negative side write voltage Vwn is a voltage lower than the second negative voltage side threshold voltage Vtnn. By applying the negative side write voltage Vwn to the upper electrode 20, a high resistance state is realized on the positive voltage side, and data “1” is written to the selected cell.

When writing data “0” to the selected cell, the positive side write voltage Vwp is applied to the upper electrode 20. The positive side write voltage Vwp is a voltage higher than the second positive voltage side threshold voltage Vtnp. By applying the positive side write voltage Vwp to the upper electrode 20, a low resistance state is realized on the positive voltage side, and data “0” is written to the selected cell.

In the fourth operation example, when writing data “1” to the selected cell, assuming that the data stored in the selected cell is data “0”, a current flows if the negative side write voltage Vwn is lower than the first negative voltage side threshold voltage Vtpn even if the negative side write voltage Vwn is higher than the second negative voltage side threshold voltage Vtnn. For this reason, data “1” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or a potential change caused by the difference between a current that flows when data is “1” and a current that flows when data is “0”.

In addition, in the case of the fourth operation example, regardless of whether the data of the selected cell is data “1” or data “0”, the application of the positive side read voltage Vrp does not destroy the data. In other words, in the case of the fourth operation example, non-destructive reading is possible regardless of whether the data of the selected cell is data “1” or data “0”.

### Second Modification Example

A memory device according to a second modification example of the third embodiment is different from the memory device according to the third embodiment in that the current-voltage characteristics of the memory elements are different.

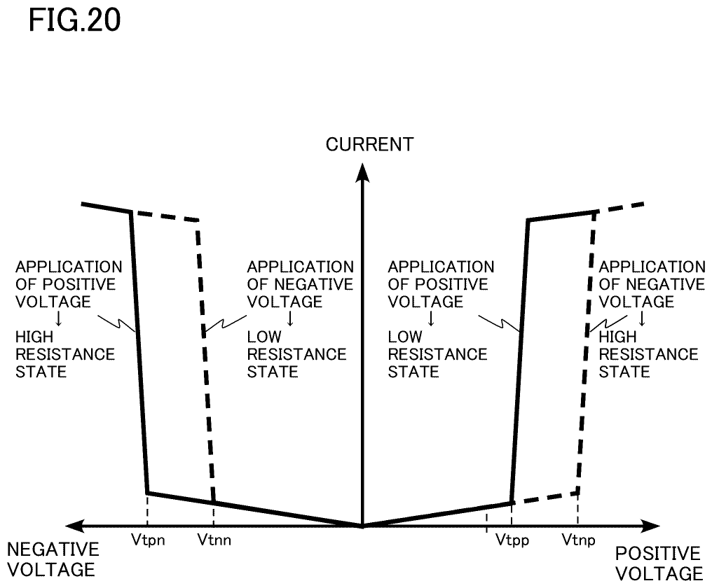

FIG. 20 is an explanatory diagram of the current-voltage characteristics of a memory element according to the second modification example of the third embodiment. The horizontal axis indicates a voltage applied to the memory element, and the vertical axis indicates a current flowing through the memory element. In FIG. 20, the horizontal axis indicates a voltage applied to the upper electrode 20 with the potential of the lower electrode 10 as a reference. FIG. 20 shows the current-voltage characteristics of the memory layer 60 in the second modification example of the third embodiment. FIG. 20 shows the current-voltage characteristics of the memory cell MC in the second modification example of the third embodiment.

The memory element according to the second modification example of the third embodiment shows different current-voltage characteristics when a predetermined positive voltage is applied to the upper electrode 20 and when a predetermined negative voltage is applied to the upper electrode 20. In FIG. 20, the solid line indicates the current-voltage characteristics when a predetermined positive voltage is applied to the upper electrode 20, and the dotted line indicates the current-voltage characteristics when a predetermined negative voltage is applied to the upper electrode 20.

When a predetermined positive voltage is applied to the upper electrode 20, the current increases abruptly at a first positive voltage side threshold voltage Vtpp on the positive voltage side. In addition, when a predetermined positive voltage is applied to the upper electrode 20, the current increases abruptly at a first negative voltage side threshold voltage Vtpn on the negative voltage side.

On the other hand, when a predetermined negative voltage is applied to the upper electrode 20, the current increases abruptly at a second positive voltage side threshold voltage Vtnp on the positive voltage side. In addition, when a predetermined negative voltage is applied to the upper electrode 20, the current increases abruptly at a second negative voltage side threshold voltage Vtnn on the negative voltage side.

The first positive voltage side threshold voltage Vtpp is lower than the second positive voltage side threshold voltage Vtnp. In addition, the first negative voltage side threshold voltage Vtpn is lower than the second negative voltage side threshold voltage Vtnn.

The memory element according to the second modification example of the third embodiment can have a high resistance state and a low resistance state on both the positive voltage side and the negative voltage side. When a predetermined positive voltage is applied to the upper electrode 20, a low resistance state is realized on the positive voltage side and a high resistance state is realized on the negative voltage side. On the other hand, when a predetermined negative voltage is applied to the upper electrode 20, a high resistance state is realized on the positive voltage side and a low resistance state is realized on the negative voltage side. Hereinafter, the high resistance state will be defined as data “1”, and the low resistance state will be defined as data “0”. The memory cell MC can store 1-bit data of “0” and “1”.

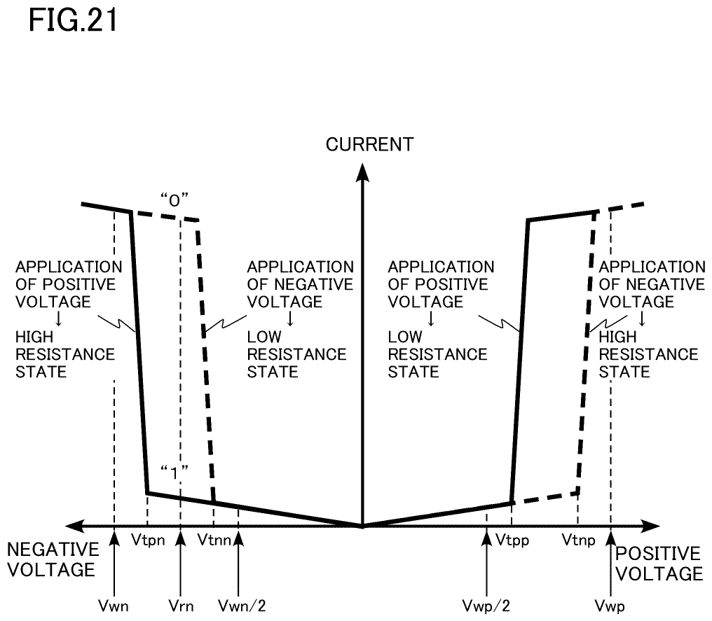

FIG. 21 is an explanatory diagram of a fifth operation example of the memory operation in the memory device according to the second modification example of the third embodiment. FIG. 21 shows a positive side write voltage Vwp, half (Vwp/2) the positive side write voltage Vwp, a negative side write voltage Vwn, half (Vwn/2) the negative side write voltage Vwn, and a negative side read voltage Vrn when performing a memory operation.

In the fifth operation example, the high resistance state and the low resistance state on the negative voltage side are used for the memory operation. In the fifth operation example, the negative side read voltage Vrn is used as a read voltage.

When writing data “1” to the selected cell, the positive side write voltage Vwp is applied to the upper electrode 20. The positive side write voltage Vwp is a voltage higher than the second positive voltage side threshold voltage Vtnp. By applying the positive side write voltage Vwp to the upper electrode 20, a high resistance state is realized on the negative voltage side, and data “1” is written to the selected cell.

When writing data “0” to the selected cell, the negative side write voltage Vwn is applied to the upper electrode 20. The negative side write voltage Vwn is a voltage lower than the first negative voltage side threshold voltage Vtpn. By applying the negative side write voltage Vwn to the upper electrode 20, a low resistance state is realized on the negative voltage side, and data “0” is written to the selected cell.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or a potential change caused by the difference between a current that flows when data is “1” and a current that flows when data is “0”.

In addition, in the case of the fifth operation example, regardless of whether the data of the selected cell is data “1” or data “0”, the application of the negative side read voltage Vrn does not destroy the data. In other words, in the case of the fifth operation example, non-destructive reading is possible regardless of whether the data of the selected cell is data “1” or data “0”.

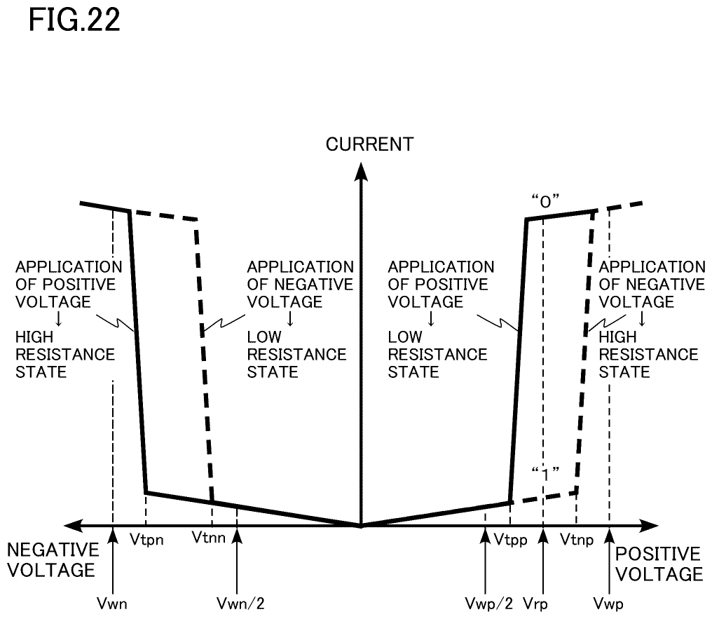

FIG. 22 is an explanatory diagram of a sixth operation example of the memory operation in the memory device according to the second modification example of the third embodiment. FIG. 22 shows a positive side write voltage Vwp, half (Vwp/2) the positive side write voltage Vwp, a negative side write voltage Vwn, half (Vwn/2) the negative side write voltage Vwn, and a positive side read voltage Vrp when performing a memory operation.

In the sixth operation example, the high resistance state and the low resistance state on the positive voltage side are used for the memory operation. In the sixth operation example, the positive side read voltage Vrp is used as a read voltage.

When writing data “1” to the selected cell, the negative side write voltage Vwn is applied to the upper electrode 20. The negative side write voltage Vwn is a voltage lower than the first negative voltage side threshold voltage Vtpn. By applying the negative side write voltage Vwn to the upper electrode 20, a high resistance state is realized on the positive voltage side, and data “1” is written to the selected cell.

When writing data “0” to the selected cell, the positive side write voltage Vwp is applied to the upper electrode 20. The positive side write voltage Vwp is a voltage higher than the second positive voltage side threshold voltage Vtnp. By applying the positive side write voltage Vwp to the upper electrode 20, a low resistance state is realized on the positive voltage side, and data “0” is written to the selected cell.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or a potential change caused by the difference between a current that flows when data is “1” and a current that flows when data is “0”.

In addition, in the case of the sixth operation example, regardless of whether the data of the selected cell is data “1” or data “0”, the application of the positive side read voltage Vrp does not destroy the data. In other words, in the case of the sixth operation example, non-destructive reading is possible regardless of whether the data of the selected cell is data “1” or data “0”.

### Third Modification Example

A memory device according to a third modification example of the third embodiment is different from the memory device according to the third embodiment in that the current-voltage characteristics of the memory elements are different.

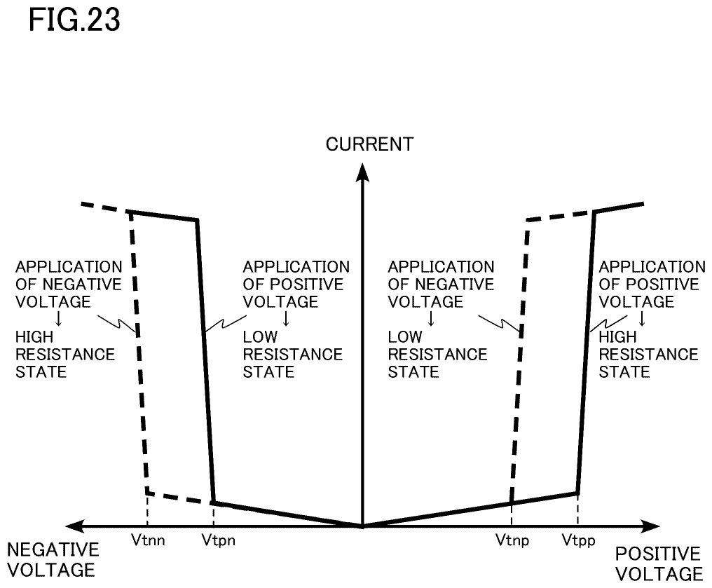

FIG. 23 is an explanatory diagram of the current-voltage characteristics of a memory element according to the third modification example of the third embodiment. The horizontal axis indicates a voltage applied to the memory element, and the vertical axis indicates a current flowing through the memory element. In FIG. 23, the horizontal axis indicates a voltage applied to the upper electrode 20 with the potential of the lower electrode 10 as a reference. FIG. 23 shows the current-voltage characteristics of the memory layer 60 in the third modification example of the third embodiment. FIG. 23 shows the current-voltage characteristics of the memory cell MC in the third modification example of the third embodiment.

The memory element according to the third modification example of the third embodiment shows different current-voltage characteristics when a predetermined positive voltage is applied to the upper electrode 20 and when a predetermined negative voltage is applied to the upper electrode 20. In FIG. 23, the solid line indicates the current-voltage characteristics when a predetermined positive voltage is applied to the upper electrode 20, and the dotted line indicates the current-voltage characteristics when a predetermined negative voltage is applied to the upper electrode 20.

When a predetermined positive voltage is applied to the upper electrode 20, the current increases abruptly at a first positive voltage side threshold voltage Vtpp on the positive voltage side. In addition, when a predetermined positive voltage is applied to the upper electrode 20, the current increases abruptly at a first negative voltage side threshold voltage Vtpn on the negative voltage side.

On the other hand, when a predetermined negative voltage is applied to the upper electrode 20, the current increases abruptly at a second positive voltage side threshold voltage Vtnp on the positive voltage side. In addition, when a predetermined negative voltage is applied to the upper electrode 20, the current increases abruptly at a second negative voltage side threshold voltage Vtnn on the negative voltage side.

The first positive voltage side threshold voltage Vtpp is higher than the second positive voltage side threshold voltage Vtnp. In addition, the first negative voltage side threshold voltage Vtpn is higher than the second negative voltage side threshold voltage Vtnn.

The memory element according to the third modification example of the third embodiment can have a high resistance state and a low resistance state on both the positive voltage side and the negative voltage side. When a predetermined positive voltage is applied to the upper electrode 20, a high resistance state is realized on the positive voltage side and a low resistance state is realized on the negative voltage side. On the other hand, when a predetermined negative voltage is applied to the upper electrode 20, a low resistance state is realized on the positive voltage side and a high resistance state is realized on the negative voltage side. Hereinafter, the high resistance state will be defined as data “1”, and the low resistance state will be defined as data “0”. The memory cell MC can store 1-bit data of “0” and “1”.

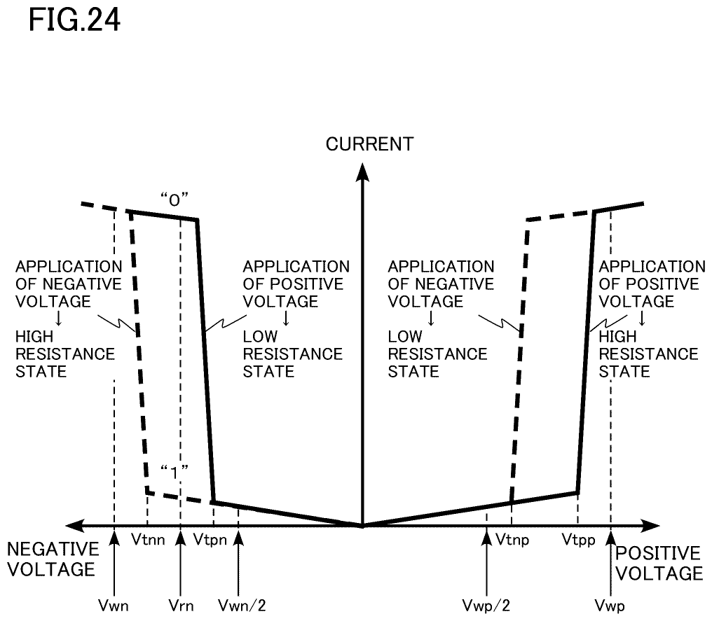

FIG. 24 is an explanatory diagram of a seventh operation example of the memory operation in the memory device according to the third modification example of the third embodiment. FIG. 24 shows a positive side write voltage Vwp, half (Vwp/2) the positive side write voltage Vwp, a negative side write voltage Vwn, half (Vwn/2) the negative side write voltage Vwn, and a negative side read voltage Vrn when performing a memory operation.

In the seventh operation example, the high resistance state and the low resistance state on the negative voltage side are used for the memory operation. In the seventh operation example, the negative side read voltage Vrn is used as a read voltage.

When writing data “1” to the selected cell, the negative side write voltage Vwn is applied to the upper electrode 20. The negative side write voltage Vwn is a voltage lower than the second negative voltage side threshold voltage Vtnn. By applying the negative side write voltage Vwn to the upper electrode 20, a high resistance state is realized on the negative voltage side, and data “1” is written to the selected cell.

When writing data “0” to the selected cell, the positive side write voltage Vwp is applied to the upper electrode 20. The positive side write voltage Vwp is a voltage higher than the first positive voltage side threshold voltage Vtpp. By applying the positive side write voltage Vwp to the upper electrode 20, a low resistance state is realized on the negative voltage side, and data “0” is written to the selected cell.

In the seventh operation example, when writing data “1” to the selected cell, assuming that the data stored in the selected cell is data “0”, a current flows if the negative side write voltage Vwn is lower than the first negative voltage side threshold voltage Vtpn even if the negative side write voltage Vwn is higher than the second negative voltage side threshold voltage Vtnn. For this reason, data “1” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, in the seventh operation example, when writing data “0” to the selected cell, assuming that the data stored in the selected cell is data “1”, a current flows if the positive side write voltage Vwp is higher than the second positive voltage side threshold voltage Vtnp even if the positive side write voltage Vwp is lower than the first positive voltage side threshold voltage Vtpp. For this reason, data “0” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or a potential change caused by the difference between a current that flows when data is “1” and a current that flows when data is “0”.

In addition, in the case of the seventh operation example, when the data of the selected cell is data “1”, the application of the negative side read voltage Vrn does not destroy the data. In other words, in the case of the seventh operation example, non-destructive reading is possible if the data of the selected cell is data “1”.

On the other hand, when the data of the selected cell is data “0”, the application of the negative side read voltage Vrn lower than the first negative voltage side threshold voltage Vtpn may cause a current to flow. As a result, the data of the selected cell may change to data “1”. In other words, in the case of the seventh operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

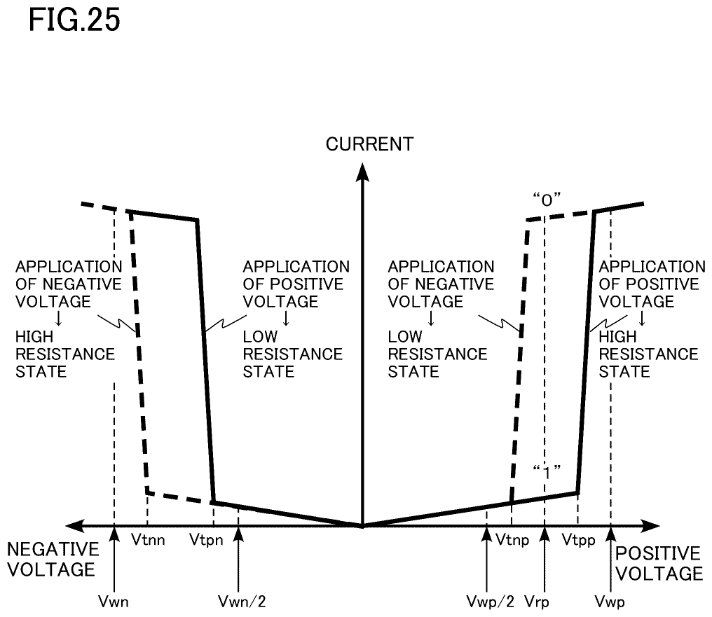

FIG. 25 is an explanatory diagram of an eighth operation example of the memory operation in the memory device according to the third modification example of the third embodiment. FIG. 25 shows a positive side write voltage Vwp, half (Vwp/2) the positive side write voltage Vwp, a negative side write voltage Vwn, half (Vwn/2) the negative side write voltage Vwn, and a positive side read voltage Vrp when performing a memory operation.

In the eighth operation example, the high resistance state and the low resistance state on the positive voltage side are used for the memory operation. In the eighth operation example, the positive side read voltage Vrp is used as a read voltage.

When writing data “1” to the selected cell, the positive side write voltage Vwp is applied to the upper electrode 20. The positive side write voltage Vwp is a voltage higher than the first positive voltage side threshold voltage Vtpp. By applying the positive side write voltage Vwp to the upper electrode 20, a high resistance state is realized on the positive voltage side, and data “1” is written to the selected cell.

When writing data “0” to the selected cell, the negative side write voltage Vwn is applied to the upper electrode 20. The negative side write voltage Vwn is a voltage lower than the second negative voltage side threshold voltage Vtnn. By applying the negative side write voltage Vwn to the upper electrode 20, a low resistance state is realized on the positive voltage side, and data “0” is written to the selected cell.

In the eighth operation example, when writing data “1” to the selected cell, assuming that the data stored in the selected cell is data “0”, a current flows if the positive side write voltage Vwp is higher than the second positive voltage side threshold voltage Vtnp even if the positive side write voltage Vwp is lower than the first positive voltage side threshold voltage Vtpp. For this reason, data “1” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, in the eighth operation example, when writing data “0” to the selected cell, assuming that the data stored in the selected cell is data “1”, a current flows if the negative side write voltage Vwn is lower than the first negative voltage side threshold voltage Vtpn even if the negative side write voltage Vwn is higher than the second negative voltage side threshold voltage Vtnn. For this reason, data “0” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or a potential change caused by the difference between a current that flows when data is “1” and a current that flows when data is “0”.

In addition, in the case of the eighth operation example, when the data of the selected cell is data “1”, the application of the positive side read voltage Vrp does not destroy the data. In other words, in the case of the eighth operation example, non-destructive reading is possible if the data of the selected cell is data “1”.

On the other hand, when the data of the selected cell is data “0”, the application of the positive side read voltage Vrp higher than the second positive voltage side threshold voltage Vtnp may cause a current to flow. As a result, the data of the selected cell may change to data “1”. In other words, in the case of the eighth operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

In the memory devices according to the third embodiment and its modification examples, the memory element of the memory cell MC has a switching function and an information storage function. The memory layer 60 is a single layer and realizes the function of the switching layer 40 and the function of the variable resistance layer 50 in the first and second embodiments. Since the memory layer 60 in the third embodiment is a single layer and has a switching function and a memory function, the structure of the memory cell MC can be made very simple.

In addition, the memory layer 60 of each memory device according to the third embodiment and its modification examples has the same configuration as the switching layer 40 in the first and second embodiments. Therefore, according to the third embodiment and its modification examples, as in the first and second embodiments, it is possible to realize a memory device having excellent switching characteristics of low half-select leakage current and high reliability.

In addition, the plurality of current-voltage characteristics of the memory elements shown in the third embodiment and its modification examples can be realized, for example, by adopting the memory layer 60 having an appropriate chemical composition.

### Fourth Embodiment

A memory device according to a fourth embodiment includes a memory cell including: a first conductive layer; a second conductive layer; a third conductive layer provided between the first conductive layer and the second conductive layer; a variable resistance layer provided between the first conductive layer and the third conductive layer; and a switching layer provided between the third conductive layer and the second conductive layer. The switching layer contains at least one of an oxide of aluminum (Al) or an oxynitride of aluminum (Al) and a compound of a first element and a second element. The first element is at least one element selected from a group consisting of zinc (Zn), tin (Sn), gallium (Ga), indium (In), and bismuth (Bi). The second element is at least one element selected from a group consisting of tellurium (Te), sulfur (S), and selenium (Se). The memory device according to the fourth embodiment is different from the memory device according to the first embodiment in that the switching layer contains an oxide of aluminum (Al) or an oxynitride of aluminum (Al). Hereinafter, the description of a part of the content overlapping the first embodiment may be omitted.

In addition, the memory device according to the fourth embodiment further includes a plurality of first wirings and a plurality of second wirings crossing the plurality of first wirings. In addition, the memory cell is provided in a region where one of the plurality of first wirings and one of the plurality of second wirings cross each other.

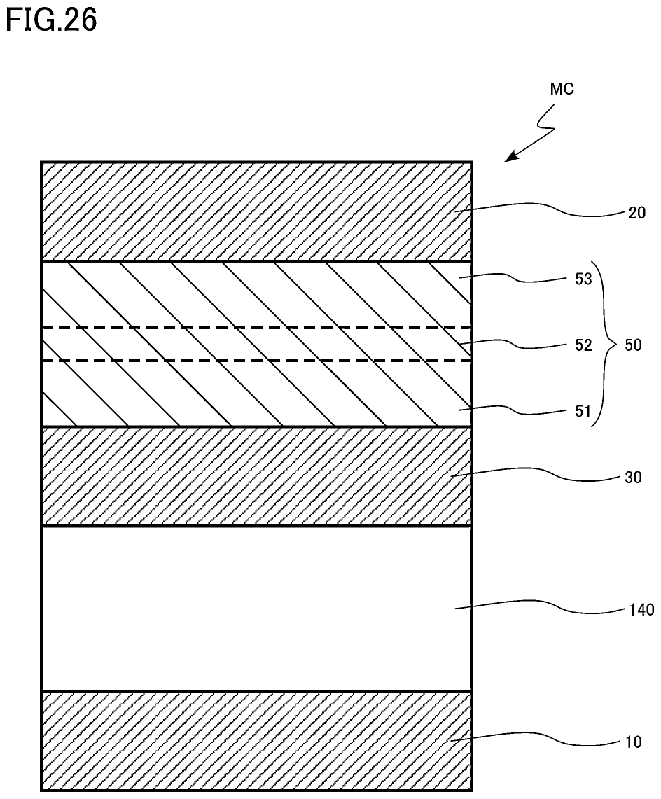

FIG. 26 is a schematic cross-sectional view of a memory cell in the memory device according to the fourth embodiment. FIG. 26 shows a cross section of one memory cell MC in a memory cell array similar to the memory cell array 100 of FIG. 1.

As shown in FIG. 26, the memory cell MC includes a lower electrode 10, an upper electrode 20, an intermediate electrode 30, a switching layer 140, and a variable resistance layer 50. The variable resistance layer 50 includes a fixed layer 51, a tunnel layer 52, and a free layer 53.

The lower electrode 10 is an example of the first conductive layer. The upper electrode 20 is an example of the second conductive layer. The intermediate electrode 30 is an example of the third conductive layer.

The lower electrode 10, the switching layer 140, and the intermediate electrode 30 form a switching element of the memory cell MC. The intermediate electrode 30, the variable resistance layer 50, and the upper electrode 20 form a variable resistance element of the memory cell MC.

The lower electrode 10 is connected to the word line 102. The lower electrode 10 is, for example, a metal. The lower electrode 10 contains, for example, at least one material selected from a group consisting of carbon, carbon nitride, tungsten, tungsten carbide, and tungsten nitride. The lower electrode 10 may be a part of the word line 102.

The upper electrode 20 is connected to the bit line 103. The upper electrode 20 is, for example, a metal. The upper electrode 20 contains, for example, at least one material selected from a group consisting of carbon, carbon nitride, tungsten, tungsten carbide, and tungsten nitride. The upper electrode 20 may be a part of the bit line 103.

The intermediate electrode 30 is provided between the lower electrode 10 and the upper electrode 20. The intermediate electrode 30 is, for example, a metal. The intermediate electrode 30 contains, for example, at least one material selected from a group consisting of carbon, carbon nitride, tungsten, tungsten carbide, and tungsten nitride.

The switching layer 140 is provided between the lower electrode 10 and the intermediate electrode 30. The thickness of the switching layer 140 in a first direction from the lower electrode 10 to the upper electrode 20 is, for example, equal to or more than 5 nm and equal to or less than 50 nm. It is preferable that the thickness of the switching layer 140 in the first direction from the lower electrode 10 to the upper electrode 20 is, for example, equal to or more than 5 nm and equal to or less than 20 nm.

The switching layer 140 has a function of suppressing an increase in half-select leakage current flowing through the half-selected cell. The switching layer 140 has a nonlinear current-voltage characteristic that a current increases abruptly at a specific threshold voltage.

The switching layer 140 contains an oxide of aluminum (Al) or an oxynitride of aluminum (Al) and a chalcogenide. The chalcogenide is a compound in which tellurium (Te), sulfur (S), or selenium (Se), which is a chalcogen element, is combined with other elements.

The switching layer 140 contains an oxide of aluminum (Al) or an oxynitride of aluminum (Al). The switching layer 140 may contain both an oxide of aluminum (Al) and an oxynitride of aluminum (Al). The switching layer 140 contains, for example, aluminum oxide or aluminum oxynitride.

Whether or not the switching layer 140 contains an oxide of aluminum (Al) or an oxynitride of aluminum (Al) can be determined by using, for example, X-ray photoelectron spectroscopy (XPS) or electron energy loss spectroscopy (EELS).

The atomic concentration of aluminum (Al) in the switching layer 140 is, for example, more than 1% and less than 40%.

The switching layer 140 may contain an oxide or oxynitride of a third element that is at least one element selected from a group consisting of zirconium (Zr), hafnium (Hf), yttrium (Y), tantalum (Ta), lanthanum (La), cerium (Ce), magnesium (Mg), titanium (Ti), scandium (Sc), vanadium (V), and niobium (Nb).

The ratio of the atomic concentration of oxygen (O) to the atomic concentration of aluminum (Al) in the switching layer 140 is, for example, equal to or more than 0.5 and equal to or less than 5.0. More preferably, the ratio of the atomic concentration of oxygen (O) to the atomic concentration of aluminum (Al) in the switching layer 140 is equal to or more than 0.5 and equal to or less than 3.0.

The switching layer 140 contains a chalcogenide that is a compound of the first element, which is at least one element selected from a group consisting of zinc (Zn), tin (Sn), gallium (Ga), indium (In), and bismuth (Bi), and the second element, which is at least one element selected from a group consisting of tellurium (Te), sulfur (S), and selenium (Se). The switching layer 140 contains a chalcogenide of the first element. The switching layer 140 contains, for example, at least one chalcogenide selected from a group consisting of zinc telluride, tin telluride, gallium telluride, indium telluride, bismuth telluride, zinc sulfide, tin sulfide, gallium sulfide, indium sulfide, bismuth sulfide, zinc selenide, tin selenide, gallium selenide, indium selenide, and bismuth selenide. The second element is more preferably tellurium (Te), and the switching layer 140 more preferably contains at least one chalcogenide selected from a group consisting of zinc telluride, tin telluride, gallium telluride, indium telluride, and bismuth telluride. Since telluride has a smaller bandgap than sulfide and selenide, the write voltage can be relatively reduced. Therefore, telluride has an advantage of being able to suppress characteristic fluctuations, such as fluctuations in half-select leakage current and fluctuations in on-current, when writing is repeated.

Whether or not the switching layer 140 contains a chalcogenide of the first element can be determined by using, for example, X-ray absorption fine structure (XAFS), Raman spectroscopy (Raman), or electron energy loss spectroscopy (EELS).

The oxide or oxynitride described above and the chalcogenide described above are, for example, main components of the switching layer 140. The fact that the oxide or oxynitride described above and the chalcogenide described above are the main components of the switching layer 140 means that there is no material having a higher mole fraction than the oxide or oxynitride described above and the chalcogenide described above among the materials contained in the switching layer 140.

The sum of the atomic concentrations of aluminum (Al), the first element, the second element, and oxygen (O) in the switching layer 140 is, for example, equal to or more than 90%.

The switching layer 140 contains, for example, a mixture of the oxide or oxynitride described above and the chalcogenide described above. The oxide or oxynitride described above and the chalcogenide described above are present in the switching layer 140, for example, in a mixed state.

The ratio of the sum of the atomic concentrations of aluminum (Al) and oxygen (O) to the sum of the atomic concentrations of aluminum (Al), the first element, the second element, and oxygen (O) in the switching layer 140 is, for example, equal to or more than 3% and equal to or less than 97%. For example, when the first element is zinc (Zn) and the second element is tellurium (Te), the ratio ((Al+O)/(Al+Zn+Te+O)) of the sum of the atomic concentrations of aluminum (Al) and oxygen (O) to the sum of the atomic concentrations of aluminum (Al), zinc (Zn), tellurium (Te), and oxygen (O) in the switching layer 140 is equal to or more than 3% and equal to or less than 97%.

The ratio of the sum of the atomic concentrations of aluminum (Al) and oxygen (O) to the sum of the atomic concentrations of aluminum (Al), the first element, the second element, and oxygen (O) in the switching layer 140 is, for example, equal to or more than 5% and less than 80%. In addition, the ratio of the absolute value of the difference between the atomic concentration of the second element and the atomic concentration of the first element to the sum of the atomic concentrations of aluminum (Al), the first element, the second element, and oxygen (O) is, for example, equal to or less than 20%.

The ratio (Al+O)/(Al+Zn+Te+O) of the sum of the atomic concentrations of aluminum (Al) and oxygen (O) to the sum of the atomic concentrations of aluminum (Al), zinc (Zn), tellurium (Te), and oxygen (O) is, for example, equal to or more than 5% and less than 80%. In addition, for example, the ratio (|Te−Zn|)/(Al+Zn+Te+O) of the absolute value of the difference between the atomic concentration of tellurium (Te) and the atomic concentration of zinc (Zn) to the sum of the atomic concentrations of aluminum (Al), zinc (Zn), tellurium (Te), and oxygen (O) is equal to or less than 20%.

The atomic concentration of the second element in the switching layer 140 is, for example, higher than the atomic concentration of the first element. For example, when the first element is zinc (Zn) and the second element is tellurium (Te), the atomic concentration of tellurium (Te) in the switching layer 140 is higher than the atomic concentration of zinc (Zn).

The switching layer 140 contains, for example, a chalcogenide formed by combining the first element and the second element and a surplus second element that does not form a chalcogenide. For example, when the first element is zinc (Zn) and the second element is tellurium (Te), zinc telluride and surplus tellurium (Te) coexist in the switching layer 140.

For example, at least a part of an oxide of aluminum (Al) or an oxynitride of aluminum (Al) contained in the switching layer 140 is crystalline. Whether or not at least a part of an oxide of aluminum (Al) or an oxynitride of aluminum (Al) contained in the switching layer 140 is crystalline can be determined by using, for example, an electron diffraction method. In addition, a part of the chalcogenide contained in the switching layer 140 may be crystalline.

The switching layer 140 contains, for example, a fourth element that is at least one element selected from a group consisting of carbon (C), boron (B), nitrogen (N), germanium (Ge), and silicon (Si). The atomic concentration of the fourth element contained in the switching layer 140 is, for example, equal to or more than 5% and equal to or less than 20%.

The switching layer 140 contains, for example, a fifth element that is at least one element selected from a group consisting of chromium (Cr), niobium (Nb), and vanadium (V). The atomic concentration of the fifth element contained in the switching layer 140 is, for example, equal to or more than 1% and equal to or less than 10%.

The switching layer 140 can be formed by using a sputtering method, for example. The switching layer 140 containing an oxide of aluminum (Al) or an oxynitride of aluminum (Al) and a chalcogenide of the first element can be formed by using, for example, a co-sputtering method using a target formed of an oxide of aluminum (Al) or an oxynitride of aluminum (Al) and a target formed of the chalcogenide of the first element. In addition, the switching layer 140 can be formed by using, for example, a sputtering method using a target formed of a mixture of the oxide of aluminum (Al) or the oxynitride of aluminum (Al) and the chalcogenide of the first element.

The variable resistance layer 50 is provided between the intermediate electrode 30 and the upper electrode 20. The variable resistance layer 50 includes the fixed layer 51, the tunnel layer 52, and the free layer 53. The variable resistance layer 50 includes a magnetic tunnel junction formed by the fixed layer 51, the tunnel layer 52, and the free layer 53.

The variable resistance layer 50 has a function of storing data by resistance change. The variable resistance layer 50 has, for example, a characteristic that the electrical resistance changes with the application of a predetermined voltage.

Next, the function and effect of the memory device according to the fourth embodiment will be described.

The switching layer 140 of the switching element according to the fourth embodiment contains an oxide of aluminum (Al) or an oxynitride of aluminum (Al) and a chalcogenide of the first element. Since the switching layer 140 contains an oxide of aluminum (Al) or an oxynitride of aluminum (Al) and a chalcogenide of the first element, a low half-select leakage current and suppression of characteristic fluctuations can be realized as in the switching element according to the first embodiment. In addition, the first element, the second element, and the third element in the switching element according to the fourth embodiment correspond to the second element, the third element, and the first element in the switching element according to the first embodiment, respectively.

In the switching element according to the fourth embodiment, since the switching layer 140 contains an oxide of aluminum (Al) or an oxynitride of aluminum (Al), the reduction rate of the half-select leakage current when reducing the area of the switching element is increased compared with the switching element according to the first embodiment. Therefore, the switching element according to the fourth embodiment can further reduce the half-select leakage current compared with the switching element according to the first embodiment.

It is preferable that the atomic concentration of aluminum (Al) in the switching layer 140 is more than 1% and less than 40%. Satisfying the above range further improves the characteristics of the switching element.

The ratio of the atomic concentration of oxygen (O) to the atomic concentration of aluminum (Al) in the switching layer 140 is preferably equal to or more than 0.5 and equal to or less than 5.0, more preferably equal to or more than 0.5 and equal to or less than 3.0. Satisfying the above range further improves the characteristics of the switching element.

For example, the ratio of the sum of the atomic concentrations of aluminum (Al) and oxygen (O) to the sum of the atomic concentrations of aluminum (Al), the first element, the second element, and oxygen (O) in the switching layer 140 is preferably equal to or more than 3% and equal to or less than 97%, more preferably equal to or more than 5% and less than 80%, even more preferably equal to or more than 10% and less than 60%, and most preferably equal to or more than 20% and less than 50%. Satisfying the above range further improves the characteristics of the switching element.

In addition, it is preferable that the ratio of the sum of the atomic concentrations of aluminum (Al) and oxygen (O) to the sum of the atomic concentrations of aluminum (Al), the first element, the second element, and oxygen (O) in the switching layer 140 is, for example, equal to or more than 5% and less than 80%. In addition, the ratio of the absolute value of the difference between the atomic concentration of the second element and the atomic concentration of the first element to the sum of the atomic concentrations of aluminum (Al), the first element, the second element, and oxygen (O) is preferably equal to or less than 20%, more preferably equal to or less than 10%, and even more preferably equal to or less than 5%. Satisfying the above range further improves the characteristics of the switching element.

That is, it is preferable that, in the switching layer 140, the atomic concentration of tellurium (Te) is higher than the atomic concentration of zinc (Zn), the ratio of the sum of the atomic concentrations of aluminum (Al) and oxygen (O) to the sum of the atomic concentrations of aluminum (Al), zinc (Zn), tellurium (Te), and oxygen (O) is equal to or more than 5% and less than 80%, and the ratio of the difference between the atomic concentration of tellurium (Te) and the atomic concentration of zinc (Zn) to the sum of the atomic concentrations of aluminum (Al), zinc (Zn), tellurium (Te), and oxygen (O) is equal to or more than 5% and equal to or less than 20%.

It is preferable that the atomic concentration of the second element in the switching layer 140 is higher than the atomic concentration of the first element. Since the atomic concentration of the second element is higher than the atomic concentration of the first element, the characteristics of the switching element are further improved.

From the viewpoint of further improving the characteristics of the switching element, it is preferable that the switching layer 140 contains a fourth element that is at least one element selected from a group consisting of carbon (C), boron (B), nitrogen (N), germanium (Ge), and silicon (Si). From the viewpoint of further improving the characteristics of the switching element, it is preferable that the atomic concentration of the fourth element contained in the switching layer 140 is equal to or more than 5% and equal to or less than 20%.

From the viewpoint of further improving the characteristics of the switching element, it is preferable that the switching layer 140 contains a fifth element that is at least one element selected from a group consisting of chromium (Cr), niobium (Nb), and vanadium (V). From the viewpoint of further improving the characteristics of the switching element, it is preferable that the atomic concentration of the fifth element contained in the switching layer 140 is equal to or more than 1% and equal to or less than 10%. It is thought that the aggregation of the chalcogenide of the first element is suppressed because the switching layer 140 contains the fifth element.

In particular, when the switching layer 140 contains an oxynitride of aluminum (Al), the characteristics of the switching element are further improved if the switching layer 140 contains a fifth element that is at least one element selected from a group consisting of chromium (Cr), niobium (Nb), and vanadium (V).

From the viewpoint of further improving the characteristics of the switching element, it is preferable that at least a part of the oxide of aluminum (Al) or the oxynitride of aluminum (Al) contained in the switching layer 140 is crystalline. It is thought that diffusion of aluminum (Al) is suppressed by making at least a part of the oxide of aluminum (Al) or the oxynitride of aluminum (Al) crystalline and accordingly, an increase in leakage current due to the separated aluminum (Al) can be suppressed.

### First Modification Example

A memory device according to a first modification example of the fourth embodiment is different from the memory device according to the fourth embodiment in that a first conductive layer includes a first portion and a second portion and the first portion contains at least one element selected from hafnium (Hf), aluminum (Al), magnesium (Mg), zirconium (Zr), and titanium (Ti).

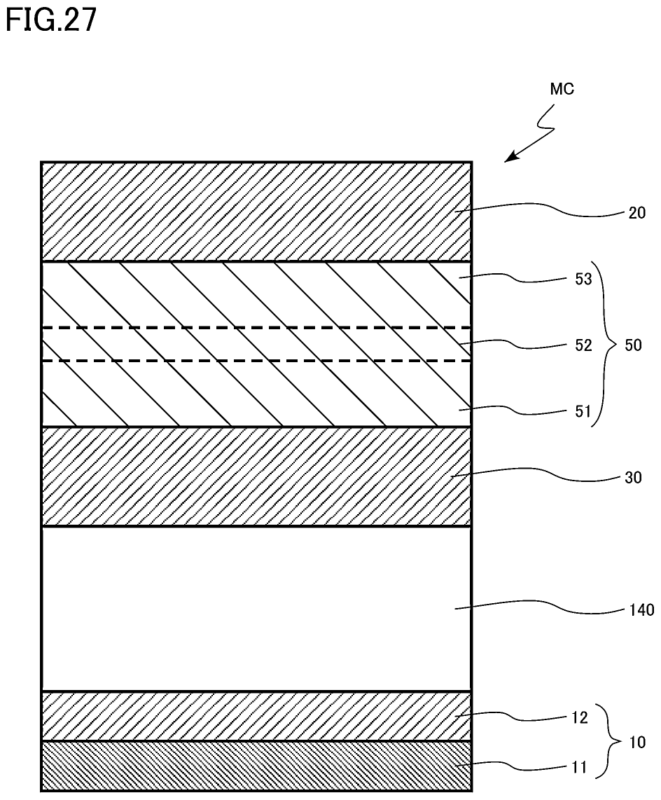

FIG. 27 is a schematic cross-sectional view of a memory cell in the memory device according to the first modification example of the fourth embodiment. FIG. 27 is a diagram corresponding to FIG. 26 of the fourth embodiment.

The lower electrode 10 includes a first portion 11 and a second portion 12. The second portion 12 is provided between the first portion 11 and the switching layer 140.

The first portion 11 contains at least one element selected from hafnium (Hf), aluminum (Al), magnesium (Mg), zirconium (Zr), and titanium (Ti). The first portion 11 contains, for example, borides of the above elements. The first portion 11 contains, for example, at least one material selected from a group consisting of hafnium, hafnium boride, magnesium aluminum boride, zirconium, zirconium boride, and titanium boride.

The second portion 12 contains, for example, at least one material selected from a group consisting of carbon, carbon nitride, tungsten, tungsten carbide, and tungsten nitride.

In the memory device according to the first modification example of the fourth embodiment, since the first portion 11 of the lower electrode 10 contains at least one element selected from hafnium (Hf), aluminum (Al), magnesium (Mg), zirconium (Zr), and titanium (Ti), degradation of the characteristics of the variable resistance element is suppressed. In addition, since the first portion 11 is not in contact with the switching layer 140, desorption of oxygen (O) from the switching layer 140 is suppressed and accordingly, degradation of the characteristics of the switching element is suppressed.

As described above, according to the first modification example of the fourth embodiment, as in the fourth embodiment, it is possible to realize a switching element having excellent characteristics of low half-select leakage current and high reliability.

### Second Modification Example

A memory device according to a second modification example of the fourth embodiment is different from the memory device according to the fourth embodiment in that a first conductive layer includes a first portion and a second portion, the first portion contains at least one element selected from hafnium (Hf), aluminum (Al), magnesium (Mg), zirconium (Zr), and titanium (Ti), a second conductive layer contains one element selected from hafnium (Hf), aluminum (Al), magnesium (Mg), zirconium (Zr), and titanium (Ti), a third conductive layer includes a third portion and a fourth portion, and the fourth portion contains at least one element selected from hafnium (Hf), aluminum (Al), magnesium (Mg), zirconium (Zr), and titanium (Ti).

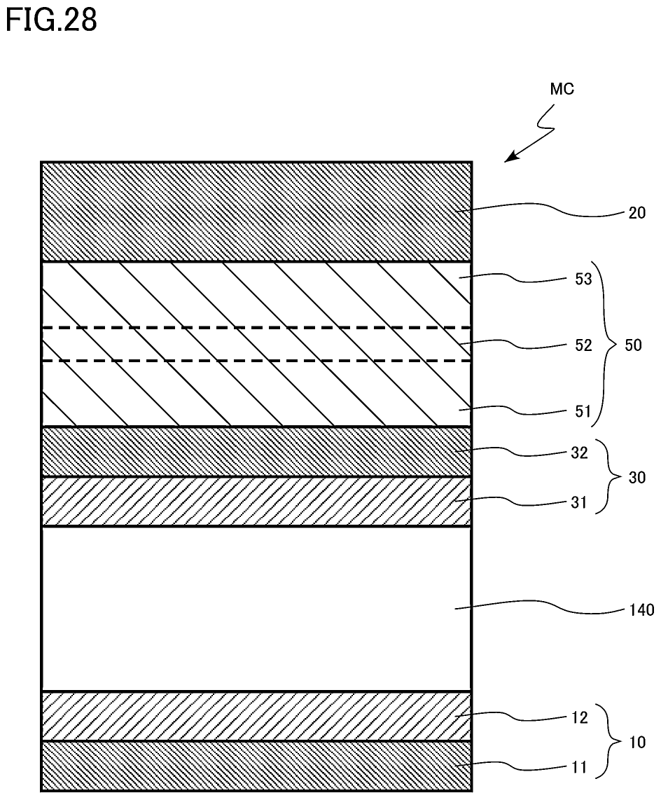

FIG. 28 is a schematic cross-sectional view of a memory cell in the memory device according to the second modification example of the fourth embodiment. FIG. 28 is a diagram corresponding to FIG. 26 of the fourth embodiment.

The lower electrode 10 includes a first portion 11 and a second portion 12. The second portion 12 is provided between the first portion 11 and the switching layer 140.

The first portion 11 contains at least one element selected from hafnium (Hf), aluminum (Al), magnesium (Mg), zirconium (Zr), and titanium (Ti). The first portion 11 contains, for example, borides of the above elements. The first portion 11 contains, for example, at least one material selected from a group consisting of hafnium, hafnium boride, magnesium aluminum boride, zirconium, zirconium boride, and titanium boride.

The second portion 12 contains, for example, at least one material selected from a group consisting of carbon, carbon nitride, tungsten, tungsten carbide, and tungsten nitride.

The upper electrode 20 contains at least one element selected from hafnium (Hf), aluminum (Al), magnesium (Mg), zirconium (Zr), and titanium (Ti). The upper electrode 20 contains, for example, borides of the above elements. The upper electrode 20 contains, for example, at least one material selected from a group consisting of hafnium, hafnium boride, magnesium aluminum boride, zirconium, zirconium boride, and titanium boride.

The intermediate electrode 30 includes a third portion 31 and a fourth portion 32. The third portion 31 is provided between the fourth portion 32 and the switching layer 140.

The third portion 31 contains, for example, at least one material selected from a group consisting of carbon, carbon nitride, tungsten, tungsten carbide, and tungsten nitride.

The fourth portion 32 contains at least one element selected from hafnium (Hf), aluminum (Al), magnesium (Mg), zirconium (Zr), and titanium (Ti). The fourth portion 32 contains, for example, borides of the above elements. The fourth portion 32 contains, for example, at least one material selected from a group consisting of hafnium, hafnium boride, magnesium aluminum boride, zirconium, zirconium boride, and titanium boride.

In the memory device according to the second modification example of the fourth embodiment, since the first portion 11 of the lower electrode 10, the upper electrode 20, and the fourth portion 32 of the intermediate electrode 30 contain at least one element selected from hafnium (Hf), aluminum (Al), magnesium (Mg), zirconium (Zr), and titanium (Ti), degradation of the characteristics of the variable resistance element is suppressed. In addition, since the first portion 11 of the lower electrode 10, the upper electrode 20, and the fourth portion 32 of the intermediate electrode 30 are not in contact with the switching layer 140, desorption of oxygen (O) from the switching layer 140 is suppressed and accordingly, degradation of the characteristics of the switching element is suppressed.

As described above, according to the second modification example of the fourth embodiment, as in the fourth embodiment, it is possible to realize a switching element having excellent characteristics of low half-select leakage current and high reliability.

### Third Modification Example

A memory device according to a third modification example of the fourth embodiment is different from the memory device according to the fourth embodiment in that a first conductive layer includes a first portion, a second portion, and a fifth portion, the first portion contains at least one element selected from hafnium (Hf), aluminum (Al), magnesium (Mg), zirconium (Zr), and titanium (Ti), a second conductive layer contains at least one element selected from hafnium (Hf), aluminum (Al), magnesium (Mg), zirconium (Zr), and titanium (Ti), a third conductive layer includes a third portion and a fourth portion, and the fourth portion contains at least one element selected from hafnium (Hf), aluminum (Al), magnesium (Mg), zirconium (Zr), and titanium (Ti).

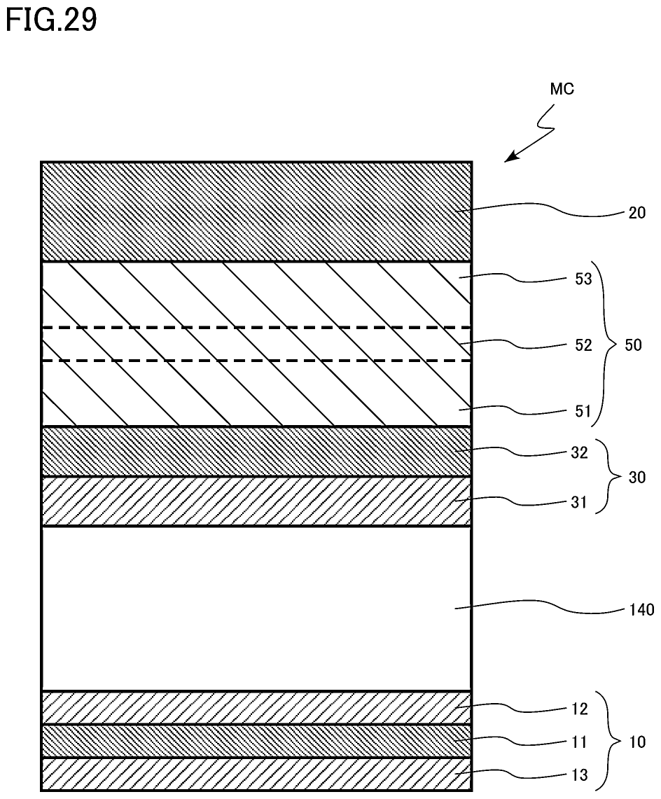

FIG. 29 is a schematic cross-sectional view of a memory cell in the memory device according to the third modification example of the fourth embodiment. FIG. 29 is a diagram corresponding to FIG. 26 of the fourth embodiment.

The lower electrode 10 includes a first portion 11, a second portion 12, and a fifth portion 13. The second portion 12 is provided between the first portion 11 and the switching layer 140. The first portion 11 is provided between the fifth portion 13 and the second portion 12.

The first portion 11 contains at least one element selected from hafnium (Hf), aluminum (Al), magnesium (Mg), zirconium (Zr), and titanium (Ti). The first portion 11 contains, for example, borides of the above elements. The first portion 11 contains, for example, at least one material selected from a group consisting of hafnium, hafnium boride, magnesium aluminum boride, zirconium, zirconium boride, and titanium boride.

The second portion 12 and the fifth portion 13 contain, for example, at least one material selected from a group consisting of carbon, carbon nitride, tungsten, tungsten carbide, and tungsten nitride.

The upper electrode 20 contains at least one element selected from hafnium (Hf), aluminum (Al), magnesium (Mg), zirconium (Zr), and titanium (Ti). The upper electrode 20 contains, for example, borides of the above elements. The upper electrode 20 contains, for example, at least one material selected from a group consisting of hafnium, hafnium boride, magnesium aluminum boride, zirconium, zirconium boride, and titanium boride.

The intermediate electrode 30 includes a third portion 31 and a fourth portion 32. The third portion 31 is provided between the fourth portion 32 and the switching layer 140.

The third portion 31 contains, for example, at least one material selected from a group consisting of carbon, carbon nitride, tungsten, tungsten carbide, and tungsten nitride.

The fourth portion 32 contains at least one element selected from hafnium (Hf), aluminum (Al), magnesium (Mg), zirconium (Zr), and titanium (Ti). The fourth portion 32 contains, for example, borides of the above elements. The fourth portion 32 contains, for example, at least one material selected from a group consisting of hafnium, hafnium boride, magnesium aluminum boride, zirconium, zirconium boride, and titanium boride.

In the memory device according to the third modification example of the fourth embodiment, since the first portion 11 of the lower electrode 10, the upper electrode 20, and the fourth portion 32 of the intermediate electrode 30 contain at least one element selected from hafnium (Hf), aluminum (Al), magnesium (Mg), zirconium (Zr), and titanium (Ti), degradation of the characteristics of the variable resistance element is suppressed. In addition, since the first portion 11 of the lower electrode 10, the upper electrode 20, and the fourth portion 32 of the intermediate electrode 30 are not in contact with the switching layer 140, desorption of oxygen (O) from the switching layer 140 is suppressed and accordingly, degradation of the characteristics of the switching element is suppressed.

As described above, according to the third modification example of the fourth embodiment, as in the fourth embodiment, it is possible to realize a switching element having excellent characteristics of low half-select leakage current and high reliability.

According to the fourth embodiment and its modification examples, it is possible to realize a switching element having excellent characteristics of low half-select leakage current and high reliability.

Therefore, according to the fourth embodiment and its modification examples, it is possible to realize a memory device having a switching element with excellent characteristics.

### Fifth Embodiment

A memory device according to a fifth embodiment is different from the memory device according to the fourth embodiment in that the memory device according to the fifth embodiment is a resistive RAM (ReRAM). Hereinafter, the description of a part of the content overlapping the fourth embodiment will be omitted.

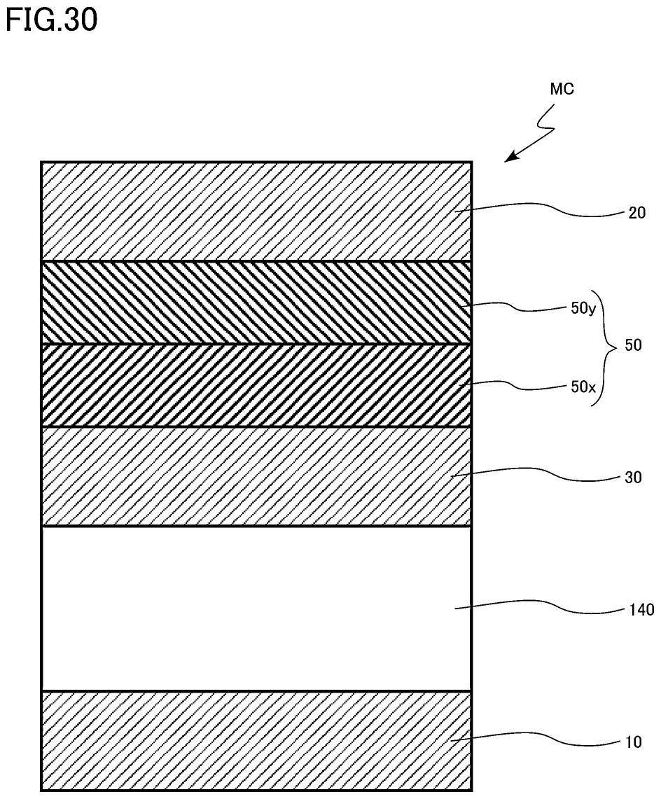

FIG. 30 is a schematic cross-sectional view of a memory cell in the memory device according to the fifth embodiment. FIG. 30 shows a cross section of one memory cell MC in a memory cell array similar to the memory cell array 100 of FIG. 1.

As shown in FIG. 30, the memory cell MC includes a lower electrode 10, an upper electrode 20, an intermediate electrode 30, a switching layer 140, and a variable resistance layer 50. The variable resistance layer 50 includes a high resistance layer 50x and a low resistance layer 50y.

The lower electrode 10 is an example of the first conductive layer. The upper electrode 20 is an example of the second conductive layer. The intermediate electrode 30 is an example of the third conductive layer.

The lower electrode 10, the switching layer 140, and the intermediate electrode 30 form a switching element of the memory cell MC. The intermediate electrode 30, the variable resistance layer 50, and the upper electrode 20 form a variable resistance element of the memory cell MC.

The configuration of the switching layer 140 is similar to that in the memory device according to the fourth embodiment.

The variable resistance layer 50 includes a high resistance layer 50x and a low resistance layer 50y.

The high resistance layer 50x is, for example, a metal oxide. The high resistance layer 50x is, for example, an aluminum oxide, a hafnium oxide, a zirconium oxide, a tantalum oxide, or a niobium oxide.

The low resistance layer 50y is, for example, a metal oxide. The low resistance layer 50y is, for example, a titanium oxide, a niobium oxide, a tantalum oxide, or a tungsten oxide.

The variable resistance layer 50 has a function of storing data by resistance change. The variable resistance layer 50 has, for example, a characteristic that the electrical resistance changes with the application of a predetermined voltage.

As described above, according to the memory device of the fifth embodiment, as in the fourth embodiment, it is possible to realize a switching element having excellent characteristics of low half-select leakage current and high reliability. Therefore, according to the fifth embodiment, it is possible to realize a memory device having a switching element with excellent characteristics.

### Sixth Embodiment

A memory device according to a sixth embodiment includes a memory cell including: a first conductive layer; a second conductive layer; and a memory layer provided between the first conductive layer and the second conductive layer. The memory layer contains at least one of an oxide of aluminum (Al) or an oxynitride of aluminum (Al) and a compound of a first element and a second element. The first element is at least one element selected from a group consisting of zinc (Zn), tin (Sn), gallium (Ga), indium (In), and bismuth (Bi). The second element is at least one element selected from a group consisting of tellurium (Te), sulfur (S), and selenium (Se). The memory device according to the sixth embodiment is different from the memory device according to the third embodiment in that the memory layer contains an oxide of aluminum (Al) or an oxynitride of aluminum (Al). Hereinafter, the description of a part of the content overlapping the third embodiment may be omitted.

In addition, the memory device according to the sixth embodiment further includes a plurality of first wirings and a plurality of second wirings crossing the plurality of first wirings. In addition, the memory cell is provided in a region where one of the plurality of first wirings and one of the plurality of second wirings cross each other.

The memory device according to the sixth embodiment is different from the memory devices according to the fourth and fifth embodiments in that the memory cell does not include a third conductive layer and a variable resistance layer and includes the same configuration as the switching layer in the fourth and fifth embodiments as a memory layer. Hereinafter, the description of a part of the content overlapping the fourth or fifth embodiment will be omitted.

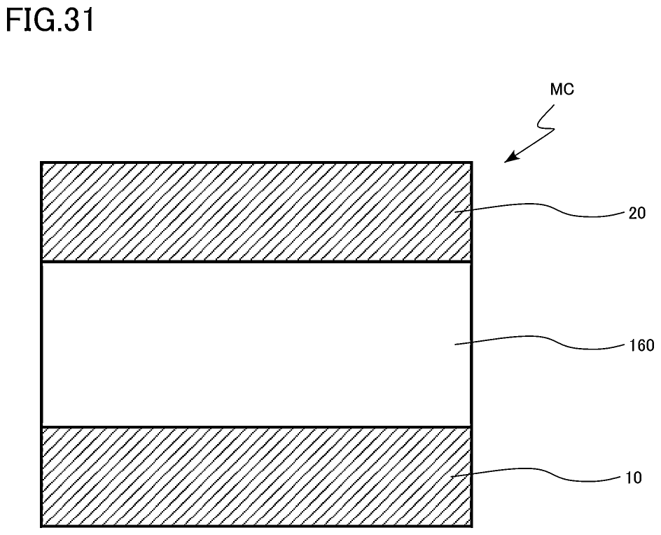

FIG. 31 is a schematic cross-sectional view of a memory cell in the memory device according to the sixth embodiment. FIG. 31 shows a cross section of one memory cell MC in a memory cell array similar to the memory cell array 100 of FIG. 1.

As shown in FIG. 31, the memory cell MC includes a lower electrode 10, an upper electrode 20, and a memory layer 160.

The lower electrode 10 is an example of the first conductive layer. The upper electrode 20 is an example of the second conductive layer.

The lower electrode 10, the memory layer 160, and the upper electrode 20 form a memory element of the memory cell MC. The memory element of the memory cell MC has a switching function and an information storage function.

The memory layer 160 has a configuration similar to that of the switching layer 140 in the fourth and fifth embodiments. That is, the memory layer 160 contains an oxide of aluminum (Al) or an oxynitride of aluminum (Al) and a compound of the first element, which is at least one element selected from a group consisting of zinc (Zn), tin (Sn), gallium (Ga), indium (In), and bismuth (Bi), and the second element, which is at least one element selected from a group consisting of tellurium (Te), sulfur (S), and selenium (Se).

The memory layer 160 has a nonlinear current-voltage characteristic that a current increases abruptly at a specific threshold voltage. In addition, the memory layer 160 has a characteristic that the threshold voltage changes with the application of a predetermined voltage. The memory layer 160 has a characteristic that the electrical resistance changes with the application of a predetermined voltage. In the sixth embodiment, the high resistance state is a state in which the resistance of the memory layer 160 is relatively high at the read voltage. In addition, in the sixth embodiment, the low resistance state is a state in which the resistance of the memory layer 160 is relatively low at the read voltage.

The memory layer 160 has a function of suppressing an increase in half-select leakage current flowing through the half-selected cell. In addition, the memory layer 160 has a function of storing data by resistance change. The memory layer 160 is a single layer and has both the function of the switching layer 140 and the function of the variable resistance layer 50 in the fourth and fifth embodiments.

In the sixth embodiment, the memory element of the memory cell MC has a switching function and an information storage function. The memory layer 160 is a single layer and realizes the function of the switching layer 140 and the function of the variable resistance layer 50 in the fourth and fifth embodiments. Since the memory layer 160 in the sixth embodiment is a single layer and has a switching function and a memory function, the structure of the memory cell MC can be made very simple.

In addition, the memory layer 160 in the sixth embodiment has a configuration similar to that of the switching layer 140 in the fourth and fifth embodiments. Therefore, according to the sixth embodiment, as in the fourth and fifth embodiments, it is possible to realize a memory device having excellent switching characteristics of low half-select leakage current and high reliability.

### Seventh Embodiment

A memory device according to a seventh embodiment includes a memory cell including: a first conductive layer; a second conductive layer; a third conductive layer provided between the first conductive layer and the second conductive layer; a variable resistance layer provided between the first conductive layer and the third conductive layer; and a switching layer provided between the third conductive layer and the second conductive layer. The switching layer contains an oxide or oxynitride of a first element and a compound of a second element and a third element. The first element is at least one element selected from a group consisting of silicon (Si), boron (B), and germanium (Ge). The second element is at least one element selected from a group consisting of zinc (Zn), tin (Sn), gallium (Ga), indium (In), and bismuth (Bi). The third element is at least one element selected from a group consisting of tellurium (Te), sulfur (S), and selenium (Se). The memory device according to the seventh embodiment is different from the memory device according to the first embodiment in that the switching layer contains an oxide or oxynitride of the first element that is at least one element selected from a group consisting of silicon (Si), boron (B), and germanium (Ge). Hereinafter, the description of a part of the content overlapping the first embodiment may be omitted.

In addition, the memory device according to the seventh embodiment further includes a plurality of first wirings and a plurality of second wirings crossing the plurality of first wirings. In addition, the memory cell is provided in a region where one of the plurality of first wirings and one of the plurality of second wirings cross each other.

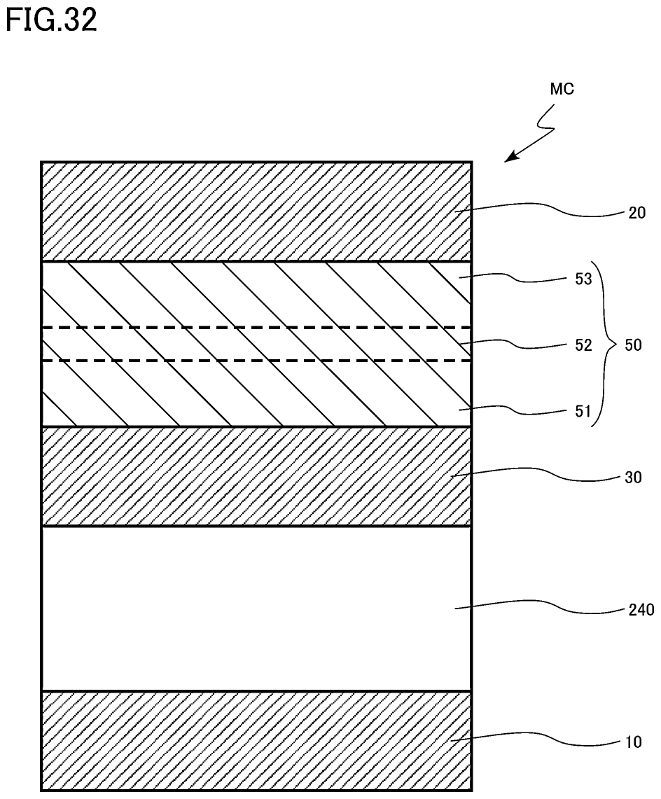

FIG. 32 is a schematic cross-sectional view of a memory cell in the memory device according to the seventh embodiment. FIG. 32 shows a cross section of one memory cell MC in a memory cell array similar to the memory cell array 100 of FIG. 1.

As shown in FIG. 32, the memory cell MC includes a lower electrode 10, an upper electrode 20, an intermediate electrode 30, a switching layer 240, and a variable resistance layer 50. The variable resistance layer 50 includes a fixed layer 51, a tunnel layer 52, and a free layer 53.

The lower electrode 10 is an example of the first conductive layer. The upper electrode 20 is an example of the second conductive layer. The intermediate electrode 30 is an example of the third conductive layer.

The lower electrode 10, the switching layer 240, and the intermediate electrode 30 form a switching element of the memory cell MC. The intermediate electrode 30, the variable resistance layer 50, and the upper electrode 20 form a variable resistance element of the memory cell MC.

The lower electrode 10 is connected to the word line 102. The lower electrode 10 is, for example, a metal. The lower electrode 10 contains, for example, at least one material selected from a group consisting of carbon, carbon nitride, tungsten, tungsten carbide, and tungsten nitride. The lower electrode 10 may be a part of the word line 102.

The upper electrode 20 is connected to the bit line 103. The upper electrode 20 is, for example, a metal. The upper electrode 20 contains, for example, at least one material selected from a group consisting of carbon, carbon nitride, tungsten, tungsten carbide, and tungsten nitride. The upper electrode 20 may be a part of the bit line 103.

The intermediate electrode 30 is provided between the lower electrode 10 and the upper electrode 20. The intermediate electrode 30 is, for example, a metal. The intermediate electrode 30 contains, for example, at least one material selected from a group consisting of carbon, carbon nitride, tungsten, tungsten carbide, and tungsten nitride.

The switching layer 240 is provided between the lower electrode 10 and the intermediate electrode 30. The thickness of the switching layer 240 in a first direction from the lower electrode 10 to the upper electrode 20 is, for example, equal to or more than 5 nm and equal to or less than 50 nm. It is preferable that the thickness of the switching layer 240 in the first direction from the lower electrode 10 to the upper electrode 20 is, for example, equal to or more than 5 nm and equal to or less than 20 nm.

The switching layer 240 has a function of suppressing an increase in half-select leakage current flowing through the half-selected cell. The switching layer 240 has a nonlinear current-voltage characteristic that a current increases abruptly at a specific threshold voltage.

The switching layer 240 contains an oxide or an oxynitride and a chalcogenide. The chalcogenide is a compound in which tellurium (Te), sulfur (S), or selenium (Se), which is a chalcogen element, is combined with other elements.

The switching layer 240 contains an oxide or oxynitride of the first element that is at least one element selected from a group consisting of silicon (Si), boron (B), and germanium (Ge). The switching layer 240 may contain both an oxide of the first element and an oxynitride of the first element. The switching layer 240 contains, for example, at least one oxide selected from a group consisting of silicon oxide, boron oxide, and germanium oxide. The switching layer 240 contains, for example, at least one oxynitride selected from a group consisting of silicon oxynitride, boron oxynitride, and germanium oxynitride.

Whether or not the switching layer 240 contains an oxide of the first element or an oxynitride of the first element can be determined by using, for example, X-ray photoelectron spectroscopy (XPS) or electron energy loss spectroscopy (EELS).

The ratio of the atomic concentration of oxygen (O) to the atomic concentration of the first element in the switching layer 240 is, for example, equal to or more than 0.5 and equal to or less than 4.0. More preferably, the ratio of the atomic concentration of oxygen (O) to the atomic concentration of the first element in the switching layer 240 is equal to or more than 0.5 and equal to or less than 3.0.

The switching layer 240 may contain an oxide or oxynitride of at least one element selected from a group consisting of zirconium (Zr), hafnium (Hf), yttrium (Y), tantalum (Ta), lanthanum (La), cerium (Ce), magnesium (Mg), titanium (Ti), scandium (Sc), vanadium (V), and niobium (Nb).

The switching layer 240 contains a chalcogenide that is a compound of the second element, which is at least one element selected from a group consisting of zinc (Zn), tin (Sn), gallium (Ga), indium (In), and bismuth (Bi), and the third element, which is at least one element selected from a group consisting of tellurium (Te), sulfur (S), and selenium (Se). The switching layer 240 contains a chalcogenide of the second element. The switching layer 240 contains, for example, at least one chalcogenide selected from a group consisting of zinc telluride, tin telluride, gallium telluride, indium telluride, bismuth telluride, zinc sulfide, tin sulfide, gallium sulfide, indium sulfide, bismuth sulfide, zinc selenide, tin selenide, gallium selenide, indium selenide, and bismuth selenide. The third element is more preferably tellurium (Te), and the switching layer 240 more preferably contains at least one chalcogenide selected from a group consisting of zinc telluride, tin telluride, gallium telluride, indium telluride, and bismuth telluride. Since telluride has a smaller bandgap than sulfide and selenide, the write voltage can be relatively reduced. Therefore, telluride has an advantage of being able to suppress characteristic fluctuations, such as fluctuations in half-select leakage current and fluctuations in on-current, when writing is repeated.

Whether or not the switching layer 240 contains a chalcogenide of the second element can be determined by using, for example, X-ray absorption fine structure (XAFS), Raman spectroscopy (Raman), or electron energy loss spectroscopy (EELS).

The oxide or oxynitride described above and the chalcogenide described above are, for example, main components of the switching layer 240. The fact that the oxide or oxynitride described above and the chalcogenide described above are the main components of the switching layer 240 means that there is no material having a higher mole fraction than the oxide described above or the chalcogenide described above among the materials contained in the switching layer 240.

The sum of the atomic concentrations of the first element, the second element, the third element, and oxygen (O) in the switching layer 240 is, for example, equal to or more than 90%.

The switching layer 240 contains, for example, a mixture of the oxide or oxynitride described above and the chalcogenide described above. The oxide or oxynitride described above and the chalcogenide described above are present in the switching layer 240, for example, in a mixed state.

The ratio of the sum of the atomic concentrations of the first element and oxygen (O) to the sum of the atomic concentrations of the first element, the second element, the third element, and oxygen (O) in the switching layer 240 is, for example, equal to or more than 3% and equal to or less than 97%.

The atomic concentration of the third element in the switching layer 240 is, for example, higher than the atomic concentration of the second element. For example, when the second element is zinc (Zn) and the third element is tellurium (Te), the atomic concentration of tellurium (Te) in the switching layer 240 is higher than the atomic concentration of zinc (Zn).

The switching layer 240 contains, for example, a chalcogenide formed by combining the second element and the third element and a surplus third element that does not form a chalcogenide. For example, when the second element is zinc (Zn) and the third element is tellurium (Te), zinc telluride and surplus tellurium (Te) coexist in the switching layer 240.

For example, at least a part of the above-described oxide or oxynitride contained in the switching layer 240 is crystalline. Whether or not at least a part of the above-described oxide or oxynitride contained in the switching layer 240 is crystalline can be determined by using, for example, an electron diffraction method. In addition, a part of the chalcogenide contained in the switching layer 240 may be crystalline.

The switching layer 240 contains, for example, carbon (C). The atomic concentration of carbon (C) contained in the switching layer 240 is, for example, equal to or more than 5% and equal to or less than 20%.

The switching layer 240 contains, for example, a fifth element that is at least one element selected from a group consisting of chromium (Cr), niobium (Nb), and vanadium (V). The atomic concentration of the fifth element contained in the switching layer 240 is, for example, equal to or more than 1% and equal to or less than 10%.

The switching layer 240 can be formed by using a sputtering method, for example. The switching layer 240 containing the oxide of the first element and the chalcogenide of the second element can be formed by using, for example, a co-sputtering method using a target formed of the oxide of the first element and a target formed of the chalcogenide of the second element. In addition, the switching layer 240 can be formed by using, for example, a sputtering method using a target formed of a mixture of the oxide of the first element and the chalcogenide of the second element.

The variable resistance layer 50 is provided between the intermediate electrode 30 and the upper electrode 20. The variable resistance layer 50 includes the fixed layer 51, the tunnel layer 52, and the free layer 53. The variable resistance layer 50 includes a magnetic tunnel junction formed by the fixed layer 51, the tunnel layer 52, and the free layer 53.

The variable resistance layer 50 has a function of storing data by resistance change. The variable resistance layer 50 has, for example, a characteristic that the electrical resistance changes with the application of a predetermined voltage.

Next, the function and effect of the memory device according to the seventh embodiment will be described.

The switching layer 240 of the switching element according to the seventh embodiment contains an oxide or oxynitride of the first element, which is at least one element selected from a group consisting of silicon (Si), boron (B), and germanium (Ge), and a chalcogenide of the second element. Since the switching layer 240 contains an oxide or oxynitride of the first element and a chalcogenide of the second element, a low half-select leakage current and suppression of characteristic fluctuations can be realized as in the switching element according to the first embodiment.

In the switching element according to the seventh embodiment, since the switching layer 240 contains an oxide or oxynitride of the first element, which is at least one element selected from a group consisting of silicon (Si), boron (B), and germanium (Ge) and has a particularly high glass-forming ability, the amorphous state is easily maintained. Therefore, with the switching element according to the seventh embodiment, it is possible to realize a lower half-select leakage current and further suppression of characteristic fluctuations compared with the switching element according to the first embodiment.

The ratio of the atomic concentration of oxygen (O) to the atomic concentration of the first element in the switching layer 240 is preferably equal to or more than 0.5 and equal to or less than 4.0, more preferably equal to or more than 0.5 and equal to or less than 3.0. Satisfying the above range further improves the characteristics of the switching element.

For example, the ratio of the sum of the atomic concentrations of the first element and oxygen (O) to the sum of the atomic concentrations of the first element, the second element, the third element, and oxygen (O) in the switching layer 240 is preferably equal to or more than 3% and equal to or less than 97%, more preferably equal to or more than 5% and less than 80%, even more preferably equal to or more than 10% and less than 60%, and most preferably equal to or more than 20% and less than 50%. Satisfying the above range further improves the characteristics of the switching element.

In addition, it is preferable that the ratio of the sum of the atomic concentrations of the first element and oxygen (O) to the sum of the atomic concentrations of the first element, the second element, the third element, and oxygen (O) in the switching layer 240 is, for example, equal to or more than 5% and less than 80%. In addition, the ratio of the absolute value of the difference between the atomic concentration of the third element and the atomic concentration of the second element to the sum of the atomic concentrations of the first element, the second element, the third element, and oxygen (O) is preferably equal to or less than 20%, more preferably equal to or less than 10%, and even more preferably equal to or less than 5%. Satisfying the above range further improves the characteristics of the switching element.

It is preferable that, in the switching layer 240, the atomic concentration of tellurium (Te) is higher than the atomic concentration of zinc (Zn), the ratio of the sum of the atomic concentrations of the first element and oxygen (O) to the sum of the atomic concentrations of the first element, zinc (Zn), tellurium (Te), and oxygen (O) is equal to or more than 5% and less than 80%, and the ratio of the difference between the atomic concentration of tellurium (Te) and the atomic concentration of zinc (Zn) to the sum of the atomic concentrations of the first element, zinc (Zn), tellurium (Te), and oxygen (O) is equal to or more than 5% and equal to or less than 20%.

It is preferable that the atomic concentration of the third element in the switching layer 240 is higher than the atomic concentration of the second element. Since the atomic concentration of the third element is higher than the atomic concentration of the second element, the characteristics of the switching element are further improved.

From the viewpoint of further improving the characteristics of the switching element, it is preferable that the switching layer 240 contains carbon (C). From the viewpoint of further improving the characteristics of the switching element, it is preferable that the atomic concentration of carbon (C) contained in the switching layer 240 is equal to or more than 5% and equal to or less than 20%.

From the viewpoint of further improving the characteristics of the switching element, it is preferable that the switching layer 240 contains a fifth element that is at least one element selected from a group consisting of chromium (Cr), niobium (Nb), and vanadium (V). From the viewpoint of further improving the characteristics of the switching element, it is preferable that the atomic concentration of the fifth element contained in the switching layer 240 is equal to or more than 1% and equal to or less than 10%. It is thought that the aggregation of the chalcogenide of the second element is suppressed because the switching layer 240 contains the fifth element.

In particular, when the switching layer 240 contains an oxynitride of the first element, the characteristics of the switching element are further improved if the switching layer 240 contains a fifth element that is at least one element selected from a group consisting of chromium (Cr), niobium (Nb), and vanadium (V).

From the viewpoint of further improving the characteristics of the switching element, it is preferable that at least a part of the oxide or oxynitride of the first element contained in the switching layer 240 is crystalline. It is thought that diffusion of the first element is suppressed by making at least a part of the oxide or oxynitride of the first element crystalline and accordingly, an increase in leakage current due to the separated first element can be suppressed.

According to the seventh embodiment, it is possible to realize a switching element having excellent characteristics of low half-select leakage current and high reliability. Therefore, according to the seventh embodiment, it is possible to realize a memory device having a switching element with excellent characteristics.

### Eighth Embodiment

A memory device according to an eighth embodiment is different from the memory device according to the seventh embodiment in that the memory device according to the eighth embodiment is a resistive RAM (ReRAM). Hereinafter, the description of a part of the content overlapping the seventh embodiment will be omitted.

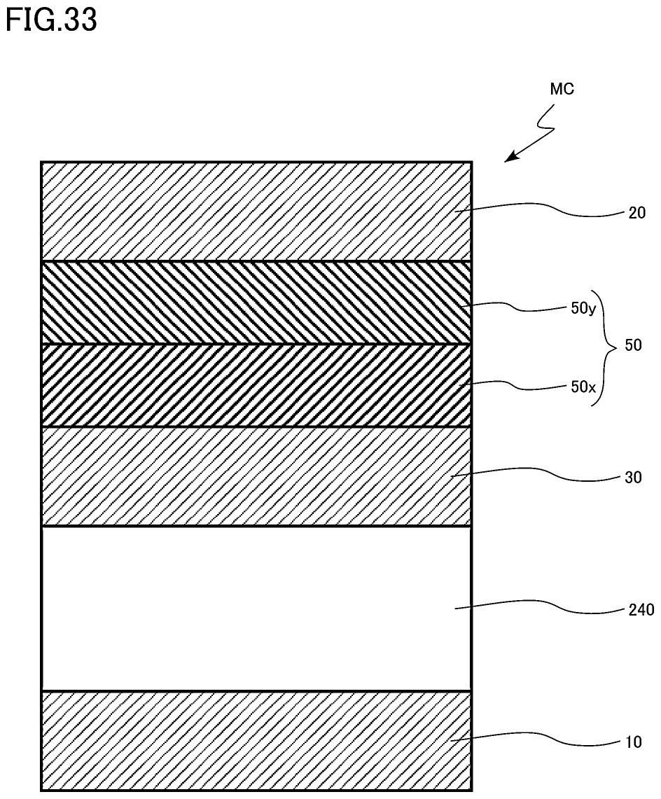

FIG. 33 is a schematic cross-sectional view of a memory cell in the memory device according to the eighth embodiment. FIG. 33 shows a cross section of one memory cell MC in a memory cell array similar to the memory cell array 100 of FIG. 1.

As shown in FIG. 33, the memory cell MC includes a lower electrode 10, an upper electrode 20, an intermediate electrode 30, a switching layer 240, and a variable resistance layer 50. The variable resistance layer 50 includes a high resistance layer 50x and a low resistance layer 50y.

The lower electrode 10 is an example of the first conductive layer. The upper electrode 20 is an example of the second conductive layer. The intermediate electrode 30 is an example of the third conductive layer.

The lower electrode 10, the switching layer 240, and the intermediate electrode 30 form a switching element of the memory cell MC. The intermediate electrode 30, the variable resistance layer 50, and the upper electrode 20 form a variable resistance element of the memory cell MC.

The configuration of the switching layer 240 is similar to that in the memory device according to the seventh embodiment.

The variable resistance layer 50 includes the high resistance layer 50x and the low resistance layer 50y.

The high resistance layer 50x is, for example, a metal oxide. The high resistance layer 50x is, for example, an aluminum oxide, a hafnium oxide, a zirconium oxide, a tantalum oxide, or a niobium oxide.

The low resistance layer 50y is, for example, a metal oxide. The low resistance layer 50y is, for example, a titanium oxide, a niobium oxide, a tantalum oxide, or a tungsten oxide.

The variable resistance layer 50 has a function of storing data by resistance change. The variable resistance layer 50 has, for example, a characteristic that the electrical resistance changes with the application of a predetermined voltage.

As described above, according to the memory device of the eighth embodiment, as in the seventh embodiment, it is possible to realize a switching element having excellent characteristics of low half-select leakage current and high reliability. Therefore, according to the eighth embodiment, it is possible to realize a memory device having a switching element with excellent characteristics.

### Ninth Embodiment

A memory device according to a ninth embodiment includes a memory cell including: a first conductive layer; a second conductive layer; and a memory layer provided between the first conductive layer and the second conductive layer. The memory layer contains an oxide or oxynitride of a first element and a compound of a second element and a third element. The first element is at least one element selected from a group consisting of silicon (Si), boron (B), and germanium (Ge). The second element is at least one element selected from a group consisting of zinc (Zn), tin (Sn), gallium (Ga), indium (In), and bismuth (Bi). The third element is at least one element selected from a group consisting of tellurium (Te), sulfur (S), and selenium (Se). The memory device according to the ninth embodiment is different from the memory device according to the third embodiment in that the memory layer contains an oxide or oxynitride of the first element that is at least one element selected from a group consisting of silicon (Si), boron (B), and germanium (Ge). Hereinafter, the description of a part of the content overlapping the third embodiment may be omitted.

In addition, the memory device according to the ninth embodiment further includes a plurality of first wirings and a plurality of second wirings crossing the plurality of first wirings. In addition, the memory cell is provided in a region where one of the plurality of first wirings and one of the plurality of second wirings cross each other.

The memory device according to the ninth embodiment is different from the memory devices according to the seventh and eighth embodiments in that the memory cell does not include a third conductive layer and a variable resistance layer and includes the same configuration as the switching layer in the seventh and eighth embodiments as a memory layer. Hereinafter, the description of a part of the content overlapping the seventh or eighth embodiment will be omitted.

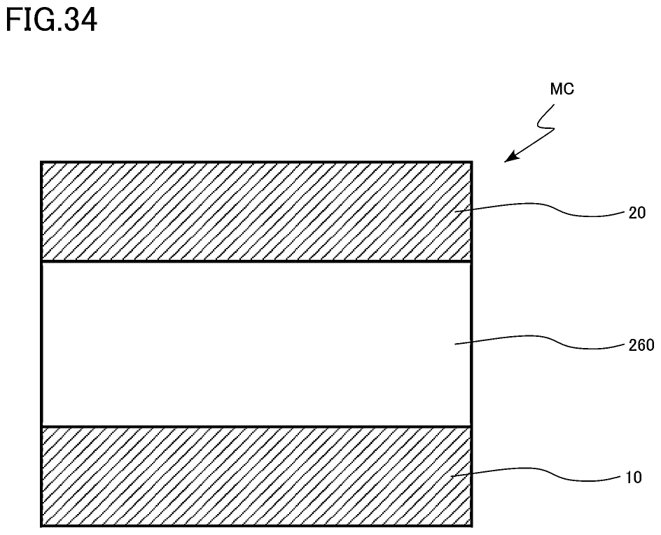

FIG. 34 is a schematic cross-sectional view of a memory cell in the memory device according to the ninth embodiment. FIG. 34 shows a cross section of one memory cell MC in a memory cell array similar to the memory cell array 100 of FIG. 1.

As shown in FIG. 34, the memory cell MC includes a lower electrode 10, an upper electrode 20, and a memory layer 260.

The lower electrode 10 is an example of the first conductive layer. The upper electrode 20 is an example of the second conductive layer.

The lower electrode 10, the memory layer 260, and the upper electrode 20 form a memory element of the memory cell MC. The memory element of the memory cell MC has a switching function and an information storage function.

The memory layer 260 has a configuration similar to that of the switching layer 240 in the seventh and eighth embodiments. That is, the memory layer 260 contains an oxide or oxynitride of the first element, which is at least one element selected from a group consisting of silicon (Si), boron (B), and germanium (Ge), and a compound of the second element that is at least one element selected from a group consisting of zinc (Zn), tin (Sn), gallium (Ga), indium (In), and bismuth (Bi) and the third element that is at least one element selected from a group consisting of tellurium (Te), sulfur (S), and selenium (Se).

The memory layer 260 has a nonlinear current-voltage characteristic that a current increases abruptly at a specific threshold voltage. In addition, the memory layer 260 has a characteristic that the threshold voltage changes with the application of a predetermined voltage. The memory layer 260 has a characteristic that the electrical resistance changes with the application of a predetermined voltage. In the ninth embodiment, the high resistance state is a state in which the resistance of the memory layer 260 is relatively high at the read voltage. In addition, in the ninth embodiment, the low resistance state is a state in which the resistance of the memory layer 260 is relatively low at the read voltage.

The memory layer 260 has a function of suppressing an increase in half-select leakage current flowing through the half-selected cell. In addition, the memory layer 260 has a function of storing data by resistance change. The memory layer 260 is a single layer and has both the function of the switching layer 240 and the function of the variable resistance layer 50 in the seventh and eighth embodiments.

In the ninth embodiment, the memory element of the memory cell MC has a switching function and an information storage function. The memory layer 260 is a single layer and realizes the function of the switching layer 240 and the function of the variable resistance layer 50 in the seventh and eighth embodiments. Since the memory layer 260 in the ninth embodiment is a single layer and has a switching function and a memory function, the structure of the memory cell MC can be made very simple.

In addition, the memory layer 260 in the ninth embodiment has a configuration similar to that of the switching layer 240 in the seventh and eighth embodiments. Therefore, according to the ninth embodiment, as in the seventh and eighth embodiments, it is possible to realize a memory device having excellent switching characteristics of low half-select leakage current and high reliability.

Although the magnetoresistive memory has been described as an example of the two-terminal memory device in the first, fourth, and seventh embodiments and the resistive RAM has been described as an example of the memory device in the second, fifth, and eighth embodiments, embodiments can be applied to other two-terminal memory devices. For example, embodiments can be applied to a phase change memory (PCM) or a ferroelectric random access memory (FeRAM).

In the first, second, and third embodiments, the case where the switching layer or the memory layer contains an oxide of the first element that is at least one element selected from a group consisting of zirconium (Zr), yttrium (Y), tantalum (Ta), lanthanum (La), cerium (Ce), titanium (Ti), hafnium (Hf), and magnesium (Mg) has been described as an example. However, the switching layer or the memory layer may contain an oxide of the first element that is at least one element selected from a group consisting of zirconium (Zr), yttrium (Y), tantalum (Ta), lanthanum (La), cerium (Ce), titanium (Ti), hafnium (Hf), magnesium (Mg), scandium (Sc), vanadium (V), and niobium (Nb).

While certain embodiments have been described, these embodiments have been presented by way of example only, and are not intended to limit the scope of the inventions. Indeed, the memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A memory device, comprising:
a memory cell including:
a first conductive layer;
a second conductive layer;
a third conductive layer provided between the first conductive layer and the second conductive layer;
a variable resistance layer provided between the first conductive layer and the third conductive layer; and
a switching layer provided between the third conductive layer and the second conductive layer,
wherein the switching layer contains an oxide of a first element and a compound of a second element and a third element,
the first element is at least one element selected from a group consisting of zirconium (Zr), yttrium (Y), tantalum (Ta), lanthanum (La), cerium (Ce), titanium (Ti), hafnium (Hf), and magnesium (Mg),
the second element is at least one element selected from a group consisting of zinc (Zn), tin (Sn), gallium (Ga), indium (In), and bismuth (Bi), and
the third element is at least one element selected from a group consisting of tellurium (Te), sulfur (S), and selenium (Se).

2. The memory device according to claim 1,
wherein the third element is tellurium (Te).

3. The memory device according to claim 1,
wherein the switching layer further contains a fourth element, and the fourth element is at least one element selected from a group consisting of carbon (C), boron (B), nitrogen (N), germanium (Ge), silicon (Si), and aluminum (Al).

4. The memory device according to claim 1,
wherein a ratio of a sum of atomic concentrations of the first element and oxygen (O) to a sum of atomic concentrations of the first element, the second element, the third element, and oxygen (O) in the switching layer is equal to or more than 3% and equal to or less than 97%.

5. The memory device according to claim 1,
wherein a ratio of a sum of atomic concentrations of the first element and oxygen (O) to a sum of atomic concentrations of the first element, the second element, the third element, and oxygen (O) in the switching layer is equal to or more than 5% and less than 80%, and
a ratio of an absolute value of a difference between the atomic concentration of the third element and the atomic concentration of the second element to the sum of the atomic concentrations of the first element, the second element, the third element, and oxygen (O) in the switching layer is equal to or less than 20%.

6. The memory device according to claim 1,
wherein an atomic concentration of the third element in the switching layer is higher than an atomic concentration of the second element,
a ratio of a sum of atomic concentrations of the first element and oxygen (O) to a sum of the atomic concentrations of the first element, the second element, the third element, and oxygen (O) in the switching layer is equal to or more than 5% and less than 80%, and
a ratio of a difference between the atomic concentration of the third element and the atomic concentration of the second element to the sum of the atomic concentrations of the first element, the second element, the third element, and oxygen (O) in the switching layer is equal to or more than 5% and equal to or less than 20%.

7. The memory device according to claim 1,
wherein a ratio of a sum of atomic concentrations of the first element and oxygen (O) to a sum of atomic concentrations of the first element, the second element, the third element, and oxygen (O) in the switching layer is equal to or more than 5% and less than 80%, and
the atomic concentration of the third element in the switching layer is higher than the atomic concentration of the second element.

8. The memory device according to claim 1,
wherein a ratio of a sum of atomic concentrations of the first element and oxygen (O) to a sum of atomic concentrations of the first element, the second element, the third element, and oxygen (O) in the switching layer is equal to or more than 5% and less than 80%, and
a ratio of an absolute value of a difference between the atomic concentration of the third element and the atomic concentration of the second element to the sum of the atomic concentrations of the first element, the second element, the third element, and oxygen (O) in the switching layer is equal to or less than 5%.

9. The memory device according to claim 1,
wherein a sum of atomic concentrations of the first element, the second element, the third element, and oxygen (O) in the switching layer is equal to or more than 90%.

10. The memory device according to claim 1,
wherein at least a part of the oxide is crystalline.

11. The memory device according to claim 1,
wherein the switching layer contains a mixture of the oxide and the compound.

12. The memory device according to claim 1,
wherein the first conductive layer, the second conductive layer, or the third conductive layer contains at least one material selected from a group consisting of carbon, carbon nitride, tungsten, tungsten carbide, and tungsten nitride.

13. The memory device according to claim 1,
wherein the first conductive layer, the second conductive layer, or the third conductive layer contains at least one material selected from a group consisting of hafnium, hafnium boride, magnesium aluminum boride, zirconium, zirconium boride, and titanium boride.

14. The memory device according to claim 1,
wherein the variable resistance layer includes a magnetic tunnel junction.

15. The memory device according to claim 1,
wherein an electrical resistance of the variable resistance layer changes with application of a predetermined voltage, and
the switching layer has a nonlinear current-voltage characteristic, and a current increases at a specific threshold voltage in the nonlinear current-voltage characteristic.

16. The memory device according to claim 1, further comprising:
a plurality of first wirings; and
a plurality of second wirings crossing the plurality of first wirings,
wherein the memory cell is provided in a region where one of the plurality of first wirings and one of the plurality of second wirings cross each other.

17. A memory device, comprising:
a memory cell including:
a first conductive layer;
a second conductive layer; and
a memory layer provided between the first conductive layer and the second conductive layer,
wherein the memory layer contains an oxide of a first element and a compound of a second element and a third element,
the first element is at least one element selected from a group consisting of zirconium (Zr), yttrium (Y), tantalum (Ta), lanthanum (La), cerium (Ce), titanium (Ti), hafnium (Hf), and magnesium (Mg),
the second element is at least one element selected from a group consisting of zinc (Zn), tin (Sn), gallium (Ga), indium (In), and bismuth (Bi), and
the third element is at least one element selected from a group consisting of tellurium (Te), sulfur (S), and selenium (Se).

18. The memory device according to claim 17,
wherein the third element is tellurium (Te).

19. The memory device according to claim 17,
wherein the memory layer has a nonlinear current-voltage characteristic, a current increases at a specific threshold voltage in the nonlinear current-voltage characteristic, and the threshold voltage changes with application of a predetermined voltage.

20. The memory device according to claim 17, further comprising:
a plurality of first wirings; and
a plurality of second wirings crossing the plurality of first wirings,
wherein the memory cell is provided in a region where one of the plurality of first wirings and one of the plurality of second wirings cross each other.

21. A memory device, comprising:
a memory cell including:
a first conductive layer;
a second conductive layer;
a third conductive layer provided between the first conductive layer and the second conductive layer;
a variable resistance layer provided between the first conductive layer and the third conductive layer; and
a switching layer provided between the third conductive layer and the second conductive layer,
wherein the switching layer contains at least one of an oxide of aluminum (Al) or an oxynitride of aluminum (Al), and a compound of a first element and a second element, and,
the first element is at least one element selected from a group consisting of zinc (Zn), tin (Sn), gallium (Ga), indium (In), and bismuth (Bi), and
the second element is at least one element selected from a group consisting of tellurium (Te), sulfur (S), and selenium (Se).

22. The memory device according to claim 21,
wherein the switching layer further contains at least one of an oxide of a third element or oxynitride of the third element, and
the third element is at least one element selected from a group consisting of zirconium (Zr), hafnium (Hf), yttrium (Y), tantalum (Ta), lanthanum (La), cerium (Ce), magnesium (Mg), titanium (Ti), scandium (Sc), vanadium (V), and niobium (Nb).

23. The memory device according to claim 21,
wherein the second element is tellurium (Te).

24. The memory device according to claim 21,
wherein an atomic concentration of aluminum (Al) in the switching layer is more than 1%.

25. The memory device according to claim 21,
wherein the switching layer further contains a fourth element, the fourth element is at least one element selected from a group consisting of carbon (C), boron (B), nitrogen (N), germanium (Ge), and silicon (Si).

26. The memory device according to claim 21,
wherein a ratio of a sum of atomic concentrations of aluminum (Al) and oxygen (O) to a sum of atomic concentrations of aluminum (Al), the first element, the second element, and oxygen (O) in the switching layer is equal to or more than 3% and equal to or less than 97%.

27. The memory device according to claim 21,
wherein a ratio of a sum of atomic concentrations of aluminum (Al) and oxygen (O) to a sum of atomic concentrations of aluminum (Al), the first element, the second element, and oxygen (O) in the switching layer is equal to or more than 5% and less than 80%, and
a ratio of an absolute value of a difference between the atomic concentration of the second element and the atomic concentration of the first element to the sum of the atomic concentrations of aluminum (Al), the first element, the second element, and oxygen (O) in the switching layer is equal to or less than 20%.

28. The memory device according to claim 21,
wherein an atomic concentration of the second element in the switching layer is higher than an atomic concentration of the first element,
a ratio of a sum of atomic concentrations of aluminum (Al) and oxygen (O) to a sum of the atomic concentrations of aluminum (Al), the first element, the second element, and oxygen (O) in the switching layer is equal to or more than 5% and less than 80%, and
a ratio of a difference between the atomic concentration of the second element and the atomic concentration of the first element to the sum of the atomic concentrations of aluminum (Al), the first element, the second element, and oxygen (O) in the switching layer is equal to or more than 5% and equal to or less than 20%.

29. The memory device according to claim 21,
wherein a ratio of a sum of atomic concentrations of aluminum (Al) and oxygen (O) to a sum of atomic concentrations of aluminum (Al), the first element, the second element, and oxygen (O) in the switching layer is equal to or more than 5% and less than 80%, and
the atomic concentration of the second element in the switching layer is higher than the atomic concentration of the first element.

30. The memory device according to claim 21,
wherein a ratio of a sum of atomic concentrations of aluminum (Al) and oxygen (O) to a sum of atomic concentrations of aluminum (Al), the first element, the second element, and oxygen (O) in the switching layer is equal to or more than 5% and less than 80%, and
a ratio of an absolute value of a difference between the atomic concentration of the second element and the atomic concentration of the first element to the sum of the atomic concentrations of aluminum (Al), the first element, the second element, and oxygen (O) in the switching layer is equal to or less than 5%.

31. The memory device according to claim 21,
wherein a sum of atomic concentrations of aluminum (Al), the first element, the second element, and oxygen (O) in the switching layer is equal to or more than 90%.

32. The memory device according to claim 21,
wherein at least a part of the oxide is crystalline.

33. The memory device according to claim 21,
wherein the switching layer contains a mixture of the oxide or the oxynitride and the compound.

34. The memory device according to claim 21,
wherein the switching layer further contains a fifth element, and the fifth element is at least one element selected from a group consisting of chromium (Cr), niobium (Nb), and vanadium (V).

35. The memory device according to claim 21,
wherein the first conductive layer, the second conductive layer, or the third conductive layer contains at least one material selected from a group consisting of carbon, carbon nitride, tungsten, tungsten carbide, and tungsten nitride.

36. The memory device according to claim 21,
wherein the first conductive layer, the second conductive layer, or the third conductive layer contains at least one material selected from a group consisting of hafnium, hafnium boride, magnesium aluminum boride, zirconium, zirconium boride, and titanium boride.

37. The memory device according to claim 21,
wherein the variable resistance layer includes a magnetic tunnel junction.

38. The memory device according to claim 21,
wherein an electrical resistance of the variable resistance layer changes with application of a predetermined voltage, and
the switching layer has a nonlinear current-voltage characteristic, and a current increases at a specific threshold voltage in the nonlinear current-voltage characteristic.

39. The memory device according to claim 21, further comprising:
a plurality of first wirings; and
a plurality of second wirings crossing the plurality of first wirings,
wherein the memory cell is provided in a region where one of the plurality of first wirings and one of the plurality of second wirings cross each other.

40. A memory device, comprising:
a memory cell including:
a first conductive layer;
a second conductive layer; and
a memory layer provided between the first conductive layer and the second conductive layer,
wherein the memory layer contains at least one of an oxide of aluminum (Al) or an oxynitride of aluminum (Al), and a compound of a first element and a second element,
the first element is at least one element selected from a group consisting of zinc (Zn), tin (Sn), gallium (Ga), indium (In), and bismuth (Bi), and
the second element is at least one element selected from a group consisting of tellurium (Te), sulfur (S), and selenium (Se).

41. The memory device according to claim 40,
wherein the memory layer further contains at least one of an oxide of a third element or oxynitride of the third element, and
the third element is at least one element selected from a group consisting of zirconium (Zr), hafnium (Hf), yttrium (Y), tantalum (Ta), lanthanum (La), cerium (Ce), magnesium (Mg), titanium (Ti), scandium (Sc), vanadium (V), and niobium (Nb).

42. The memory device according to claim 40,
wherein the second element is tellurium (Te).

43. The memory device according to claim 40,
wherein the memory layer has a nonlinear current-voltage characteristic, a current increases at a specific threshold voltage in the nonlinear current-voltage characteristic, and the threshold voltage changes with application of a predetermined voltage.

44. The memory device according to claim 40, further comprising:
a plurality of first wirings; and
a plurality of second wirings crossing the plurality of first wirings,
wherein the memory cell is provided in a region where one of the plurality of first wirings and one of the plurality of second wirings cross each other.

45. A memory device, comprising:
a memory cell including:
a first conductive layer;
a second conductive layer;
a third conductive layer provided between the first conductive layer and the second conductive layer;
a variable resistance layer provided between the first conductive layer and the third conductive layer; and
a switching layer provided between the third conductive layer and the second conductive layer,
wherein the switching layer contains an oxide of a first element and a compound of a second element and a third element,
the first element is at least one element selected from a group consisting of zirconium (Zr), yttrium (Y), tantalum (Ta), lanthanum (La), cerium (Ce), titanium (Ti), hafnium (Hf), magnesium (Mg), scandium (Sc), vanadium (V), and niobium (Nb),
the second element is at least one element selected from a group consisting of zinc (Zn), tin (Sn), gallium (Ga), indium (In), and bismuth (Bi), and
the third element is at least one element selected from a group consisting of tellurium (Te), sulfur (S), and selenium (Se).

46. A memory device, comprising:
a memory cell including:
a first conductive layer;
a second conductive layer; and
a memory layer provided between the first conductive layer and the second conductive layer,
wherein the memory layer contains an oxide of a first element and a compound of a second element and a third element,
the first element is at least one element selected from a group consisting of zirconium (Zr), yttrium (Y), tantalum (Ta), lanthanum (La), cerium (Ce), titanium (Ti), hafnium (Hf), magnesium (Mg), scandium (Sc), vanadium (V), and niobium (Nb),
the second element is at least one element selected from a group consisting of zinc (Zn), tin (Sn), gallium (Ga), indium (In), and bismuth (Bi), and
the third element is at least one element selected from a group consisting of tellurium (Te), sulfur (S), and selenium (Se).
